(19) United States
(12) Patent Application Publication
(10) Pub. No.: US 2023/0228970 A1
(43) Pub. Date: Jul. 20, 2023

(54) Electronic Device and Method For Operating The Electronic Device

(71) Applicant: Semiconductor Energy Laboratory Co., Ltd., Kanagawa-ken (JP)

(72) Inventors: Takeya Hirose, Atsugi (JP); Hisao IKEDA, Zama (JP); Ryo HATSUMI, Hadano (JP); Daiki NAKAMURA, Atsugi (JP); Yosuke TSUKAMOTO, Atsugi (JP)

(73) Assignee: Semiconductor Energy Laboratory Co., Ltd., Kanagawa-Ken (JP)

(21) Appl. No.: 18/095,117

(22) Filed: Jan. 10, 2023

(30) Foreign Application Priority Data
Jan. 14, 2022 (JP) 2022-004227

(51) Int. Cl. G02B 7/28; H10K 39/34; H10K 59/80; G06F 1/16

(52) U.S. Cl. CPC G02B 7/28; H10K 39/34; H10K 59/879; G06F 1/163; H10K 59/35

(57) ABSTRACT

A method for operating an electronic device, which is easy on eyes, is provided. The electronic device includes a display device including a light-emitting device and a light-receiving device, and a lens. The method includes a step of displaying an image for focus adjustment of a user's eye; a step of detecting a spot diameter of first light reflected by the user's eye; a step of moving the lens and detecting a spot diameter of second light reflected by the user's eye; a step of determining whether the spot diameter of the second light is smaller than the spot diameter of the first light; a step of further moving the lens and detecting a spot diameter of the third light reflected by the user's eye in the case where the spot diameter of the second light is smaller than the spot diameter of the first light; a step of determining whether the spot diameter of the third light is smaller than the spot diameter of the second light; and a step of moving the lens to a position at which the spot diameter of the first light has been detected, in the case where the spot diameter of the second light is larger than the spot diameter of the first light.

### BACKGROUND OF THE INVENTION

### 1. Field of the Invention

One embodiment of the present invention relates to a display device. One embodiment of the present invention relates to a lens. One embodiment of the present invention relates to an optical device including a display device and a lens. One embodiment of the present invention relates to an electronic device including an optical device. One embodiment of the present invention relates to a method for operating an electronic device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, a lighting device, an input device, an input/output device, an optical device, an electronic device, an operation method thereof, and a manufacturing method thereof. A semiconductor device generally means a device that can function by utilizing semiconductor characteristics.

### 2. Description of the Related Art

Wearable electronic devices are becoming widespread as electronic devices equipped with display devices for augmented reality (AR) or virtual reality (VR). Examples of wearable electronic devices include a head mounted display (HMD) and an eyeglass-type electronic device.

With an electronic device whose display portion is close to the user, such as an HMD, the user is likely to perceive pixels and strongly feels granularity, whereby the sense of immersion or realistic feeling in AR or VR might be diminished. Thus, an HMD is preferably provided with a display device that has minute pixels so that pixels are not perceived by the user. Patent Document 1 discloses a method in which an HMD including minute pixels is achieved by using minute transistors capable of high-speed operation.

### REFERENCE

### Patent Document

[Patent Document 1] Japanese Published Patent Application No. 2000-002856

### SUMMARY OF THE INVENTION

Many electronic devices each provided with a display device for AR or VR are worn on the user's head like an HMD or the like when used. Thus, the distance between a display portion of the electronic device and the user's eyes is fixed in using the electronic device. Accordingly, depending on the conditions of the user's eyes (e.g., eyesight, the width of a field of vision, and the eye fatigue level), the user cannot watch a video displayed on the display portion in the optimal condition (e.g., in the condition where the focus of the user's eyes is always adjusted regardless of the conditions of the user's eyes), which might induce problems such as increased fatigue level of the user's eyes (eyestrain).

An object of one embodiment of the present invention is to provide an electronic device offering a high sense of immersion and an operation method of the electronic device. Another object is to provide an electronic device with high display quality and an operation method of the electronic device. Another object is to provide an electronic device that is easy on the user's eyes and causes less eyestrain and an operation method of the electronic device. Another object is to provide an electronic device with low power consumption and an operation method of the electronic device.

An object of one embodiment of the present invention is to provide an optical device having a novel structure, an electronic device including the optical device having a novel structure, and operation methods of them. Another object of one embodiment of the present invention is to at least alleviate at least one problem in the conventional art.

Note that the description of these objects does not preclude the existence of other objects. One embodiment of the present invention does not necessarily achieve all the objects listed above. Objects other than these can be derived from the description of the specification, the drawings, the claims, and the like.

One embodiment of the present invention is an electronic device including a housing including an optical device. The optical device includes a display device and a lens. The display device includes a light-emitting device and a light-receiving device. The lens is positioned on the display portion side of the display device. The housing has a first function of detecting, with the use of the light-receiving device, a spot diameter of first light that is emitted from the light-emitting device and reflected by a detection target; a second function of moving the lens and detecting, with the use of the light-receiving device, a spot diameter of second light that is emitted from the light-emitting device and reflected by the detection target; a third function of determining whether the spot diameter of the second light is smaller than the spot diameter of the first light; a fourth function of further moving the lens and detecting, with the use of the light-receiving device, a spot diameter of third light that is emitted from the light-emitting device and reflected by the detection target in the case where the spot diameter of the second light is smaller than the spot diameter of the first light; a fifth function of determining whether the spot diameter of the third light is smaller than the spot diameter of the second light; and a sixth function of moving the lens to a position at which the spot diameter of the first light has been detected, in the case where the spot diameter of the second light is larger than the spot diameter of the first light.

In the above, the light-emitting device preferably has a function of emitting infrared light.

In the above, the light-receiving device preferably has a function of detecting infrared light.

In the above, the detection target is preferably a user's eye.

In the above, the diagonal of the display portion of the display device is preferably shorter than the diameter of the lens.

In the above, a pixel density of the display device is preferably higher than or equal to 1000 ppi and lower than or equal to 20000 ppi.

In the above, the display device preferably includes a plurality of light-emitting devices and a color filter, and the plurality of light-emitting devices each preferably include an organic layer emitting white light.

In the above, the organic layer is preferably divided between two adjacent light-emitting devices.

In the above, the display device preferably includes a first light-emitting device and a second light-emitting device, and the first light-emitting device and the second light-emitting device preferably include different light-emitting materials.

In the above, the housing is preferably connected to a mounting fixture, and the mounting fixture preferably has a function of fixing the housing to a user's head.

Another embodiment of the present invention is a method for operating an electronic device including an optical device including a display device and a lens, in which the display device includes a light-emitting device and a light-receiving device, and the lens is positioned on the display portion side of the display device. In the method, the optical device has a first step of displaying an image; a second step of detecting, with the use of the light-receiving device, a spot diameter of first light that is emitted from the light-emitting device and reflected by a detection target; a third step of moving the lens and detecting, with the use of the light-receiving device, a spot diameter of second light that is emitted from the light-emitting device and reflected by the detection target; a fourth step of determining whether the spot diameter of the second light is smaller than the spot diameter of the first light; a fifth step of further moving the lens and detecting, with the use of the light-receiving device, a spot diameter of third light that is emitted from the light-emitting device and reflected by the detection target in the case where the spot diameter of the second light is smaller than the spot diameter of the first light; a sixth step of determining whether the spot diameter of the third light is smaller than the spot diameter of the second light; and a seventh step of moving the lens to a position at which the spot diameter of the first light has been detected, in the case where the spot diameter of the second light is larger than the spot diameter of the first light.

In the above, in the first step, the light-emitting device preferably emits infrared light while the image is displayed.

In the above, the light-receiving device preferably detects a spot diameter of infrared light reflected by the detection target in the second step, the third step, and the fifth step.

In the above, the detection target is preferably a user's eye.

According to one embodiment of the present invention, an electronic device offering a high sense of immersion and an operation method of the electronic device can be provided. Alternatively, an electronic device with high display quality and an operation method of the electronic device can be provided. Alternatively, an electronic device that is easy on the user's eyes and causes less eyestrain and an operation method of the electronic device can be provided. Alternatively, an electronic device with low power consumption and an operation method of the electronic device can be provided.

According to one embodiment of the present invention, an optical device having a novel structure, an electronic device including the optical device having a novel structure, and operation methods of them can be provided. According to one embodiment of the present invention, at least one problem in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

In the accompanying drawings:

FIG. 1 illustrates an example of light paths between an optical device included in an electronic device and a user's eye;

FIG. 2 illustrates an example of light paths between an optical device included in an electronic device and a user's eye;

FIG. 3 illustrates an example of light paths between an optical device included in an electronic device and a user's eye;

FIG. 4 illustrates an example of light paths between an optical device included in an electronic device and a user's eye;

FIG. 5 illustrates an example of light paths between an optical device included in an electronic device and a user's eye;

FIG. 6 illustrates an example of light paths between an optical device included in an electronic device and a user's eye;

FIGS. 7A to 7C each show a relation between the distance between a lens included in an electronic device and a user's eye and a spot diameter of reflected light on a display device included in the electronic device;

FIG. 8 is a flowchart showing an example of an operation method of an optical device included in an electronic device;

FIGS. 9A and 9B each illustrate an example of an image displayed by a display device included in an electronic device;

FIGS. 10A and 10B illustrate a structure example of an electronic device;

FIG. 11 illustrates an example of light paths between a display device and a user's eye;

FIG. 12A illustrates an example of light paths between a display device and a user's eye, and FIG. 12B illustrates an example of light paths inside the user's eye;

FIG. 13A illustrates an example of light paths between a display device and a user's eye, and FIG. 13B illustrates an example of light paths inside the user's eye;

FIGS. 14A and 14B are schematic views illustrating a structure example of a display device included in an electronic device, and FIGS. 14C and 14D illustrate examples of circuit diagrams of pixels included in the display device;

FIG. 15A is a plan view illustrating a structure example of a display device included in an electronic device, and FIGS. 15B and 15C are cross-sectional views illustrating a structure example of the display device included in the electronic device;

FIGS. 16A and 16B are cross-sectional views each illustrating a structure example of a display device included in an electronic device;

FIGS. 17A to 17J each illustrate an example of a pixel of a display device included in an electronic device;

FIGS. 18A and 18B are perspective views illustrating a structure example of a display device included in an electronic device;

FIG. 19 is a cross-sectional view illustrating a structure example of a display device included in an electronic device;

FIG. 20 is a cross-sectional view illustrating a structure example of a display device included in an electronic device;

FIG. 21 is a cross-sectional view illustrating a structure example of a display device included in an electronic device;

FIG. 22 is a cross-sectional view illustrating a structure example of a display device included in an electronic device;

FIG. 23 is a cross-sectional view illustrating a structure example of a display device included in an electronic device;

FIG. 24 is a cross-sectional view illustrating a structure example of a display device included in an electronic device;

FIG. 25 is a cross-sectional view illustrating a structure example of a display device included in an electronic device;

FIGS. 26A to 26F each illustrate a structure example of a light-emitting device included in a display device;

FIGS. 27A to 27C each illustrate a structure example of a light-emitting device included in a display device; and

FIGS. 28A and 28B each illustrate a structure example of a light-receiving device included in a display device.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some case. Therefore, the size, the layer thickness, or the region is not limited to the illustrated scale.

Note that in this specification and the like, ordinal numbers such as “first” and “second” are used in order to avoid confusion among components and do not limit the number of components.

In this specification and the like, a display panel that is one embodiment of a display device has a function of displaying (outputting) an image or the like on (to) a display surface. Thus, the display panel is one embodiment of an output device.

In this specification and the like, a structure in which a connector such as a flexible printed circuit (FPC) or a tape carrier package (TCP) is attached to a substrate of a display panel, or a structure in which an integrated circuit (IC) is mounted on a substrate by a chip on glass (COG) method or the like is referred to as a display panel module or a display module, or simply referred to as a display panel or the like in some cases.

### Embodiment 1

In this embodiment, an electronic device of one embodiment of the present invention and an operation method of the electronic device are described.

An electronic device of one embodiment of the present invention can be mounted on a head. The electronic device can offer a three-dimensional image using parallax to a user. That is, the electronic device can be used as a VR device. Furthermore, the electronic device may have a function of displaying scenery in front of the user, which is captured with a camera (this function is also referred to as a video see-through function). Moreover, the electronic device can perform what is called AR display in which an image is displayed to overlap with the scenery in front of the user.

Here, in the case where an electronic device provided with a VR or AR display device is the above-described electronic device that can be mounted on a head (e.g., an HMD), the distance between a display portion of the electronic device and a user's eye is fixed at the time of using the electronic device. Thus, depending on the conditions of the user's eye (e.g., eyesight, the width of a field of vision, and the eye fatigue level), the user's eye might not always be focused on the display portion of the electronic device. This situation is described in more detail with reference to drawings.

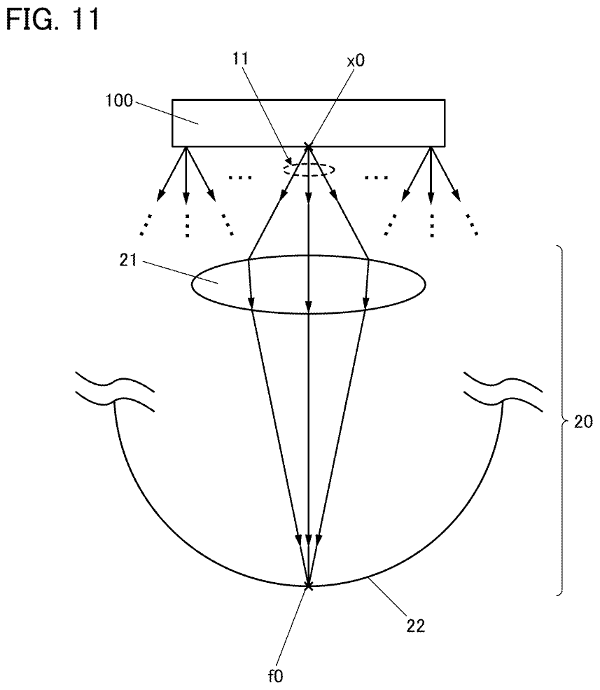

FIG. 11 is a schematic view illustrating an example of light paths between a display device 100 included in the electronic device and an eye (a right eye or a left eye) 20 of a user of the electronic device. The electronic device includes a display portion included in the display device 100. For easy understanding, the eye 20 consists of only a crystalline lens 21 and a retina 22. FIG. 11 illustrates the state where the electronic device is fixed to a user's head, and the center portions of the surface of the display device 100, the surface of the crystalline lens 21, and the surface of the retina 22 are on one straight line.

As is to be described later, the display device 100 includes a plurality of light-emitting devices (also referred to as light-emitting elements) in the display portion. Thus, a plurality of rays of light are emitted from the plurality of light-emitting devices included in the display portion. In FIG. 11, of the plurality of rays of light emitted from the display device 100, only a path of light (light 11) emitted from the light-emitting device positioned in the center portion (at a point x0) of the surface of the display portion is illustrated by a solid arrow.

In FIG. 11, the light 11 emitted from the light-emitting device at the point x0 on the display device 100 travels while spreading, and reaches to the surface of the crystalline lens 21 of the user's eye 20. The crystalline lens of a human eye functions as a lens; therefore, the light 11 is refracted by the crystalline lens 21 and travels toward the retina 22 of the user's eye 20 while being condensed. FIG. 11 illustrates the state where all rays included in the light 11 having passed the crystalline lens 21 gather at one point (point f0) on the retina 22 to form an image. That is, FIG. 11 illustrates the state where the eye of the user of the electronic device is focused on the display portion of the electronic device (i.e., the emmetropic state).

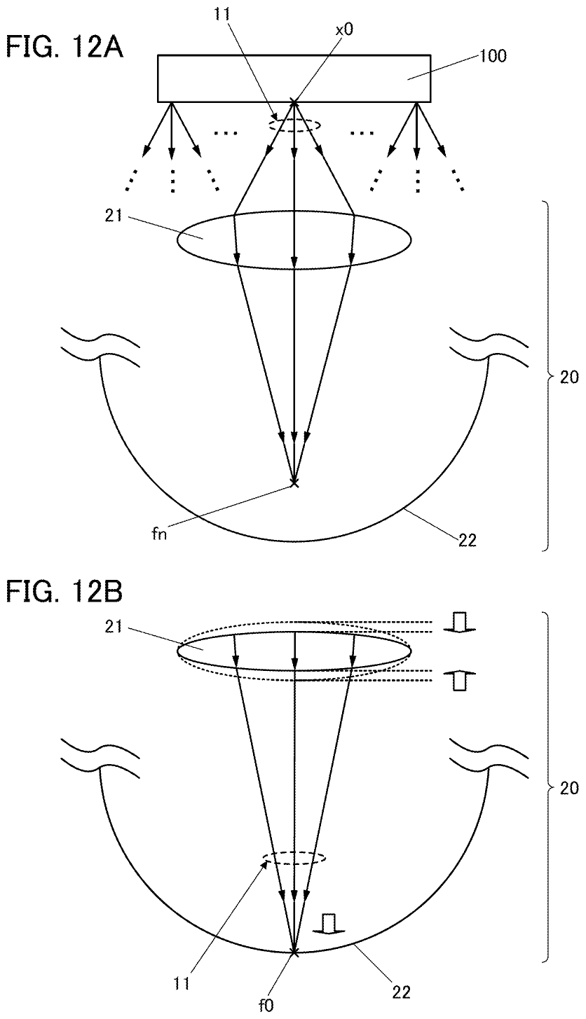

FIG. 12A is a schematic view illustrating an example of light paths between the display device 100 and the eye 20, which is different from FIG. 11. In FIG. 12A, the light 11 emitted from the light-emitting device at the point x0 on the display device 100 is refracted by the crystalline lens 21 and travels toward the retina 22 while being condensed, and an image is formed at a point fn in front of the retina 22. That is, the eye of the user of the electronic device is not focused on the display portion of the electronic device, i.e., the user's eye is in a state similar to the myopic state.

In the case where the eye of the user of the electronic device is in the above state (the myopic state), the user attempts to focus one's eye on the display portion of the electronic device. Specifically, as illustrated in FIG. 12B, the thickness of the crystalline lens 21 is reduced to increase the radius of curvature of the surface of the crystalline lens 21 so that the focal length of the crystalline lens 21 is extended. Then, the user performs focus adjustment in such a manner that the thickness of the crystalline lens 21 is adjusted so that the light 11 having passed through the crystalline lens 21 forms an image at the point f0 on the retina 22.

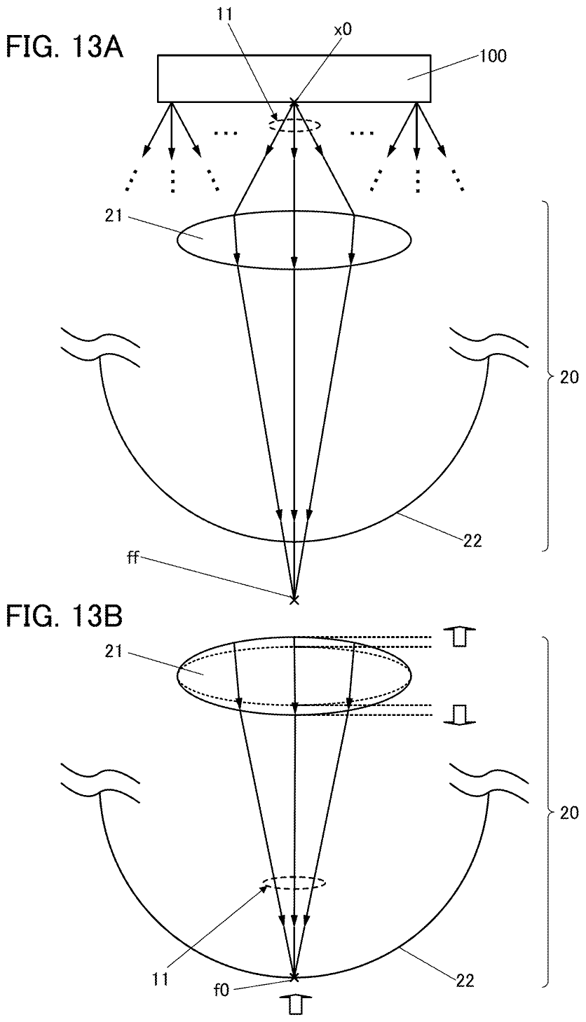

FIG. 13A is a schematic view illustrating an example of light paths between the display device 100 and the eye 20, which is different from FIG. 11 and FIG. 12A. In FIG. 13A, the light 11 emitted from the light-emitting device at the point x0 on the display device 100 is refracted by the crystalline lens 21 and travels toward the retina 22 while being condensed, and the light 11 forms an image at a point ff behind the retina 22. That is, the eye of the user of the electronic device is not focused on the display portion of the electronic device, i.e., the user's eye is in a state similar to the hyperopic state.

In the case where the eye of the user of the electronic device is in the above state (the hyperopic state), the user attempts to focus one's eye on the display portion of the electronic device. Specifically, as illustrated in FIG. 13B, the thickness of the crystalline lens 21 is increased to reduce the radius of curvature of the surface of the crystalline lens 21 so that the focal length of the crystalline lens 21 is shortened. Then, the user performs focus adjustment in such a manner that the thickness of the crystalline lens 21 is adjusted so that the light 11 having passed through the crystalline lens 21 forms an image at the point f0 on the retina 22.

Thus, the human eye can adjust the focus on a visual subject to some extent by automatically adjusting the thickness of the crystalline lens. However, adjustment of the thickness of the crystalline lens that is a part of the human body differs in individuals and the amount of thickness adjustment is limited. Furthermore, even if the focus can be adjusted by thickness adjustment of the crystalline lens, this focus adjustment also stresses the eye as compared to the normal state (the state in which the eye does not perform focus adjustment and is relaxed); thus, continuous use of the electronic device with the user's eye in this state could result in increasing the eye fatigue level (eyestrain) of the user.

In view of the above, the display portion of the electronic device of one embodiment of the present invention has a function of automatically adjusting focus of the user's eye in accordance with the state of the user's eye (e.g., eyesight, the width of a field of vision, and the eye fatigue level) without user's adjustment of the eye focus (thickness adjustment of the crystalline lens). Specifically, a movable lens for focus adjustment is provided between the display device 100 and the user's eye 20. A structure example of the electronic device of one embodiment of the present invention is described below with reference to drawings.

### Structure Example 1

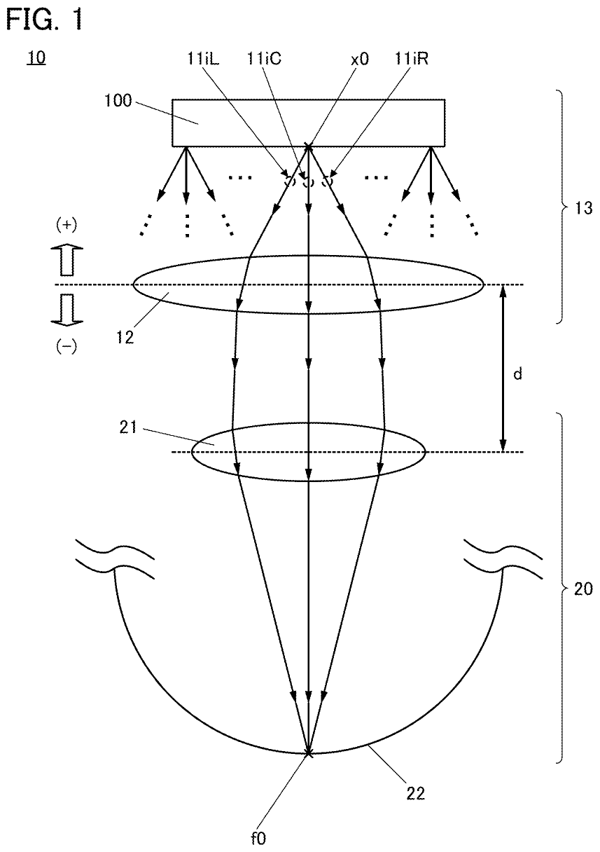

FIG. 1 is a schematic view illustrating an example of light paths between an optical device 13 included in an electronic device 10 of one embodiment of the present invention and an eye (a right eye or a left eye) 20 of a user of the electronic device 10. The optical device 13 includes at least one display device 100 and one lens 12.

The display device 100 preferably has a higher pixel density. The pixel density can be 1000 ppi or higher, preferably 2000 ppi or higher, further preferably 3000 ppi or higher, still further preferably 4000 ppi or higher, yet further preferably 5000 ppi or higher, and 20000 ppi or lower, preferably 8000 ppi or lower, for example.

A larger display portion of the display device 100 enables the thinner lens 12, and in addition, less image distortion due to the lens. For example, the diagonal of the display portion of the display device 100 can be 0.3 inches or more or 0.5 inches or more, preferably 0.7 inches or more, further preferably 1 inch or more, still further preferably 1.3 inches or more, and 2 inches or less or 1.7 inches or less. Specifically, the diagonal of the display portion is preferably 1.5 inches or a similar size.

The diagonal of the display portion of the display device 100 is preferably smaller than the diameter of the lens 12. For example, the diagonal of the display portion of the display device 100 can be 90% or less, preferably 80% or less, further preferably 70% or less of the diameter of the lens 12. Thus, the distortion of an image that can be seen through the lens 12 can be made small, increasing the sense of immersion. If the diagonal of the display portion of the display device 100 is larger than the diameter of the lens 12, part of the display portion might be out of the field of view.

Note that the pixel density of the display device 100 and the size of the display portion are not limited to the above. For example, in the case where a high definition is not required, a display device having a pixel density lower than 1000 ppi may be used, or a display device having a diagonal longer than 2 inches can be used.

The lens 12 is positioned between the display device 100 and the user's eye 20, and can also be referred to as an eye lens. A convex lens is preferably used as the lens 12. The lens 12 is a movable lens that can be moved in the normal direction of the display surface of the display device 100 between the display device 100 and the user's eye 20. In FIG. 1, the lens 12 is placed so that the distance between the center of the lens 12 and the center of the crystalline lens 21 is a distance d. In the case where the lens 12 moves to the display device 100 side from the placing position (i.e., the distance between the lens 12 and the crystalline lens 21 is longer than the distance d), this movement corresponds to movement to the +(positive) side; in the case where the lens 12 moves to the user's eye 20 side (i.e., the distance between the lens 12 and the crystalline lens 21 is shorter than the distance d), this movement corresponds to movement to the −(negative) side.

In FIG. 1, the electronic device 10 is fixed to the user's head, and the center portions of the surface of the display device 100, the surface of the lens 12, the surface of the crystalline lens 21, and the surface of the retina 22 are on one straight line. Thus, the user of the electronic device 10 can see an image displayed by the display device 100 through the lens 12.

In FIG. 1, of rays of light emitted from the point x0 on the display device 100, light going straight in a straight line connecting the center portion of the surface of the lens 12 and the center portion of the surface of the crystalline lens 21 is light 11iC indicated by a solid arrow. Of rays of light going straight in a direction oblique to the light 11iC, one is light 11iL and another is light 11iR, which are indicated by solid arrows.

Since the light 11iC passes through the center portions of the lens 12 and the crystalline lens 21 (it can be rephrased as “the light 11iC is normally incident on the lens 12 and the crystalline lens 21”), the light 11iC can keep going straight without being refracted by the lens 12 or the crystalline lens 21 to reach the point f0 on the retina 22.

On the other hand, the light 11iL and the light 11iR are refracted by the lens 12, which makes directions of the light 11iL and the light 11iR toward the light 11iC side, and the light 11iL and the light 11iR enter the crystalline lens 21. Then, the light 11iL and the light 11iR are also refracted by the crystalline lens 21, which further makes the directions of the light 11iL and the light 11iR toward the light 11iC side, and the light 11iL and the light 11iR go straight to the retina 22. In FIG. 1, all of the light 11iC, the light 11iL, and the light 11iR gather at one point (the point f0) on the retina 22 to form an image. That is, FIG. 1 illustrates the state where the eye 20 of the user of the electronic device 10 is focused on the display portion of the display device 100 (i.e., the emmetropic state).

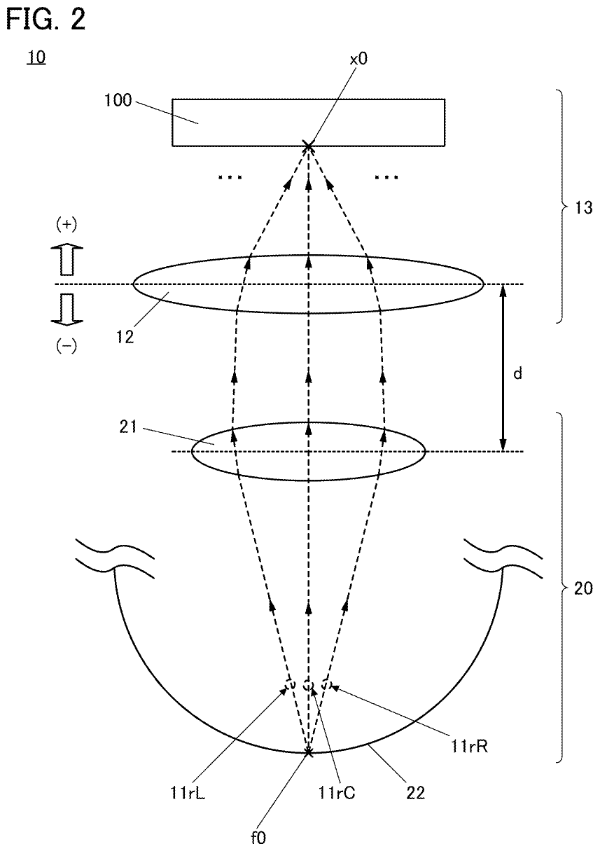

FIG. 2 illustrates an example of paths of the light 11iC, the light 11iL, and the light 11iR that have gathered at the one point (the point f0) on the retina 22 in FIG. 1 and then been reflected by the point. In FIG. 2, of rays of light reflected by the point f0 on the retina 22, light going straight to the point x0 on the display device 100 is light 11rC indicated by a dashed arrow. Of rays of light going straight in a direction oblique to the light 11rC, one is light 11rL and another is light 11rR, which are indicated by dashed arrows.

As illustrated in FIG. 2, the light 11iC incident on the point f0 on the retina 22 in FIG. 1 is reflected by the point f0 to change the moving direction, and goes straight as the light 11rC. As described above, since the light 11iC is normally incident on the lens 12 and the crystalline lens 21, the light 11rC reflected by the point f0 is also normally incident on the crystalline lens 21 and the lens 12 to pass through the center portion of each surface, and goes straight to the point x0 on the display device 100 without being refracted.

On the other hand, the light 11iL is reflected by the point f0 on the retina 22 to enter the crystalline lens 21 as light 11rR which is one ray of light going straight in a direction oblique to the light 11rC. The light 11iR is reflected by the point f0 on the retina 22 to enter the crystalline lens 21 as light 11rL which is another ray of light going straight in a direction oblique to the light 11rC. The light 11rL and the light 11rR incident on the crystalline lens 21 are refracted to change their moving directions toward the light 11rC side, and go straight to the lens 12. Then, the light 11rL and the light 11rR are also refracted by the lens 12 to further change their moving directions toward the light 11rC side, and go straight to the display device 100. In FIG. 2, all of the light 11rC, the light 11rL, and the light 11rR gather at one point (the point x0) on the display device 100 to form an image. As illustrated in FIG. 1, the point x0 is also a point from which the light 11iC, the light 11iL, and the light 11iR are emitted. Thus, in the case where the eye 20 of the user of the electronic device 10 is focused on the display portion of the display device 100, light emitted from one point on the display portion passes through the lens 12 and the crystalline lens 21 to reach one point on the retina 22, and returns to the above-mentioned one point on the display portion without fail. That is, the starting point and the returning point of light on the display portion are the same point.

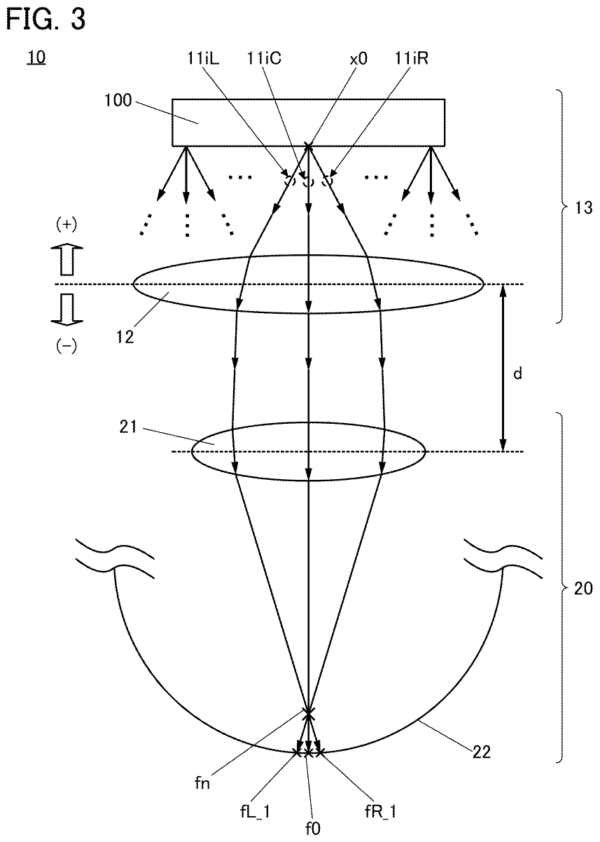

FIG. 3 illustrates an example of light paths in the case where the light 11iC, the light 11iL, and the light 11iR emitted from the one point (the point x0) on the display device 100 pass through the lens 12 and the crystalline lens 21 and then form an image at the point fn in front of the retina 22 (i.e., in the myopic state). In this case, the light 11iC passes through the point fn and then goes straight to the point f0 on the retina 22. On the other hand, the light 11iL passes through the point fn and then goes straight to a point fR_1 on the retina 22 so as to intersect the light 11iR. The light 11iR passes through the point fn and then goes straight to a point fL_1 on the retina 22 so as to intersect the light 11iL.

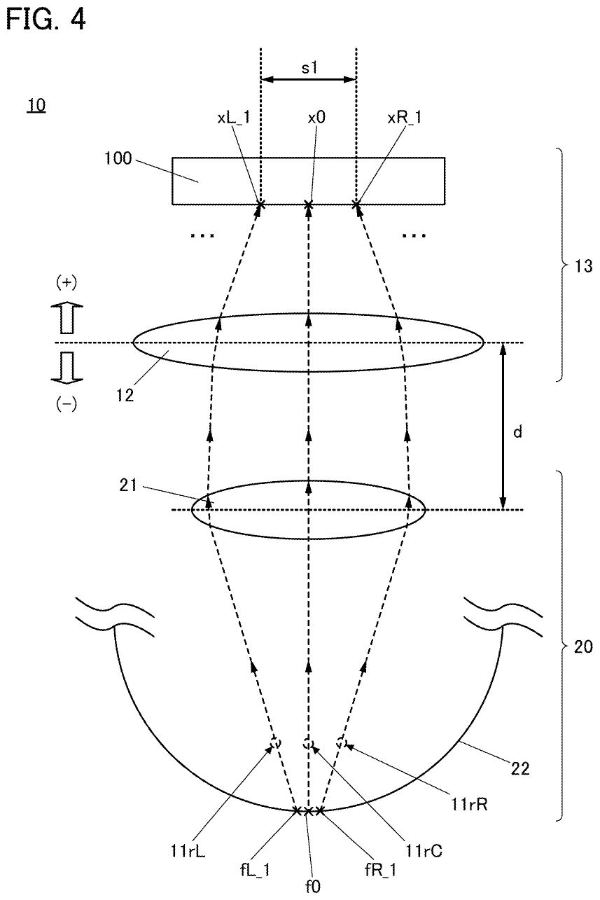

FIG. 4 illustrates an example of paths of the light 11iC, the light 11iL, and the light 11iR that reach the point f0, the point fR_1, and the point fL_1, respectively, on the retina 22 in FIG. 3 and then are reflected by the respective reaching points. In FIG. 4, light reflected by the point f0 on the retina 22 is the light 11rC indicated by a dashed arrow. Light reflected by the point fL_1 on the retina 22 is the light 11rL indicated by a dashed arrow. Light reflected by the point fR_1 on the retina 22 is the light 11rR indicated by a dashed arrow.

As illustrated in FIG. 4, the light 11iC incident on the point f0 on the retina 22 in FIG. 3 is reflected by the point f0 to change the moving direction, and goes straight as the light 11rC. As described above, since the light 11iC is normally incident on the lens 12 and the crystalline lens 21, the light 11rC reflected by the point f0 is also normally incident on the crystalline lens 21 and the lens 12 to pass through the center portion of each surface, and goes straight to the point x0 on the display device 100 without being refracted.

On the other hand, the light 11rL and the light 11rR are refracted by the crystalline lens 21 and the lens 12 to change the moving directions toward the light 11rC side, and go straight to the display device 100. The light 11rL reaches a point xL_1 to the left of the point x0 in relation to the user's eye 20. The light 11rR reaches a point xR_1 to the right of the point x0 in relation to the user's eye 20. That is, in the case where the eye 20 of the user of the electronic device 10 is not focused on the display portion of the display device 100 (in the case of the myopic state), rays of light emitted from the point x0 do not gather at the point x0 and return to different points on the display device 100. In FIG. 4, the spot diameter of light, which is emitted from the point x0 and reflected by the user's eye 20, on the display device 100 (corresponding to the distance between the point xL_1 and the point xR_1) is a spot diameter s1. As illustrated in FIG. 2, in the case where the eye 20 of the user of the electronic device 10 is focused on the display portion of the display device 100, rays of light emitted from the point x0 and reflected by the user's eye 20 all gather at the point x0. Therefore, when the spot diameter of the reflected light on the display device 100 in this case is a spot diameter s0, it can be said that the spot diameter s1 is larger than the spot diameter s0.

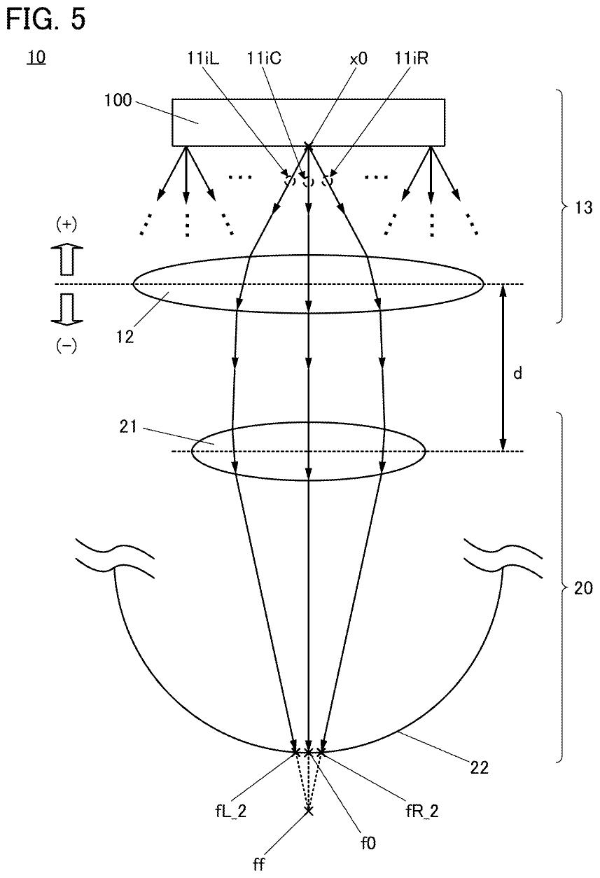

FIG. 5 illustrates an example of light paths in the case where the light 11iC, the light 11iL, and the light 11iR emitted from the one point (the point x0) on the display device 100 pass through the lens 12 and the crystalline lens 21 and then form an image at the point ff behind the retina 22 (i.e., in the hyperopic state). In this case, the light 11iC passes through the center portions of the lens 12 and the crystalline lens 21 and then goes straight to the point f0 on the retina 22. On the other hand, the light 11iL passes through the crystalline lens 21 to be refracted toward the light 11iC side, and reaches a point fL_2 on the retina 22 before intersecting the light 11iC and the light 11iR. The light 11iR passes through the crystalline lens 21 to be refracted toward the light 11iC side, and reaches a point fR_2 on the retina 22 before intersecting the light 11iC and the light 11iL.

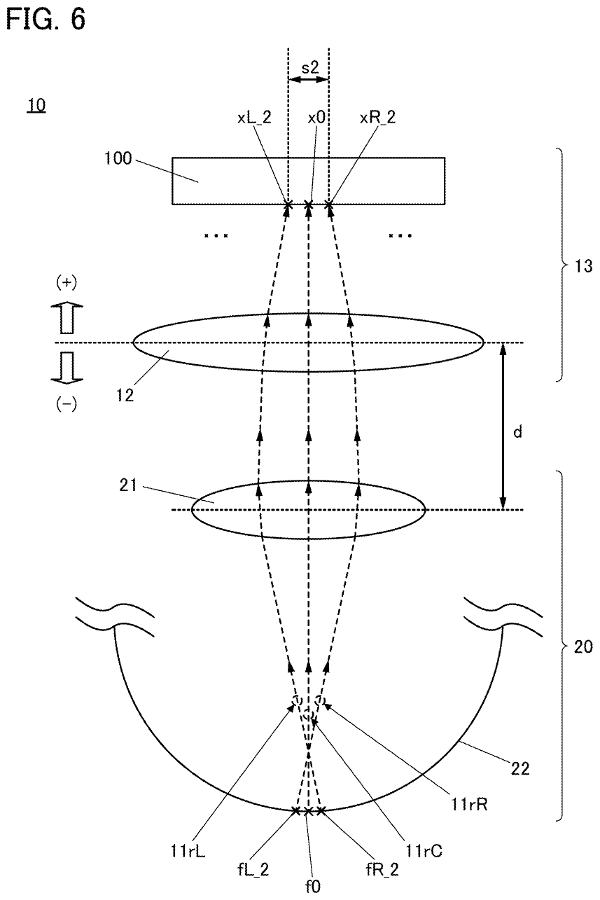

FIG. 6 illustrates an example of paths of the light 11iC, the light 11iL, and the light 11iR that reach the point f0, the point fL_2, and the point fR_2, respectively, on the retina 22 in FIG. 5 and then are reflected by the respective reaching points. In FIG. 6, light reflected by the point f0 on the retina 22 is the light 11rC indicated by a dashed arrow. Light reflected by the point fL_2 on the retina 22 is the light 11rR indicated by a dashed arrow. Light reflected by the point fR_2 on the retina 22 is the light 11rL indicated by a dashed arrow.

As illustrated in FIG. 6, the light 11iC incident on the point f0 on the retina 22 in FIG. 5 is reflected by the point f0 to change the moving direction, and goes straight as the light 11rC. As described above, since the light 11iC is normally incident on the lens 12 and the crystalline lens 21, the light 11rC reflected by the point f0 is also normally incident on the crystalline lens 21 and the lens 12 to pass through the center portion of each surface, and goes straight to the point x0 on the display device 100 without being refracted.

On the other hand, the light 11rL and the light 11rR are refracted by the crystalline lens 21 and the lens 12 to change the moving directions toward the light 11rC side, and go straight to the display device 100. The light 11rL reaches a point xL_2 to the left of the point x0 in relation to the user's eye 20. The light 11rR reaches a point xR_2 to the right of the point x0 in relation to the user's eye 20. That is, in the case where the eye 20 of the user of the electronic device 10 is not focused on the display portion of the display device 100 (in the case of the hyperopic state), rays of light emitted from the point x0 do not gather at the point x0 and return to different points on the display device 100. In FIG. 6, the spot diameter of light, which is emitted from the point x0 and reflected by the user's eye 20, on the display device 100 (corresponding to the distance between the point xL_2 and the point xR_2) is a spot diameter s2. Therefore, it can be said that the spot diameter s2 is larger than the above-described spot diameter s0.

Here, when the focal length of the lens 12 is f1, the focal length of the crystalline lens 21 (the focal length in the state where the crystalline lens 21 does not adjust its thickness) is f2, and the composite focal length of the lens 12 and the crystalline lens 21 is f, the composite focal length f can be expressed by the following Formula 1 using the focal length f1 of the lens 12, the focal length f2 of the crystalline lens 21, and the distance d between the center of the lens 12 and the center of the crystalline lens 21.

$$\begin{matrix}[ Formula 1 ] & \\ \frac{1}{f} = \frac{1}{f 1} + \frac{1}{f 2} - \frac{d}{f 1 f 2} & ( 1 )\end{matrix}$$

Thus, Formula 1 can be changed into the following Formula 2 expressing the composite focal length f of the lens 12 and the crystalline lens 21.

$$\begin{matrix}[ Formula 2 ] & \\ f = \frac{f 1 f 2}{f 1 + f 2 - d} & ( 2 )\end{matrix}$$

In Formula 2, the focal length f1 of the lens 12 and the focal length f2 of the crystalline lens 21 (the focal length in the state where the crystalline lens 21 does not adjust its thickness) are specific values. Meanwhile, since the lens 12 is the movable lens as described above, the distance d between the lens 12 and the crystalline lens 21 can be adjusted as appropriate by changing the placing position of the lens 12. That is, the composite focal length f of the lens 12 and the crystalline lens 21 can be adjusted freely by adjusting the placing position of the lens 12. Specifically, the composite focal length f of the lens 12 and the crystalline lens 21 can be made short by making the distance d between the lens 12 and the crystalline lens 21 short (by making the lens 12 close to the eye 20 of the user of the electronic device 10). In contrast, the composite focal length f of the lens 12 and the crystalline lens 21 can be made long by making the distance d between the lens 12 and the crystalline lens 21 long (by making the lens 12 distant from the eye 20 of the user of the electronic device 10).

For example, in the case where the eye 20 of the user of the electronic device 10 is in a state similar to the myopic state and is not focused on the display portion of the display device 100 as illustrated in FIG. 3, light passing through the lens 12 and the crystalline lens 21 forms an image at the point fn in front of the retina 22. In such a case, the distance d between the lens 12 and the crystalline lens 21 can be made long by moving the lens 12 toward the display device 100 side (+ side). Therefore, according to the above Formula 2, the composite focal length f of the lens 12 and the crystalline lens 21 increases, and thus a position where light passing through the crystalline lens 21 forms an image can be moved to the retina 22 side.

For example, in the case where the eye 20 of the user of the electronic device 10 is in a state similar to the hyperopic state and is not focused on the display portion of the display device 100 as illustrated in FIG. 5, light passing through the lens 12 and the crystalline lens 21 forms an image at the point ff behind the retina 22. In such a case, the distance d between the lens 12 and the crystalline lens 21 can be made short by moving the lens 12 toward the crystalline lens 21 side (− side). Therefore, according to the above Formula 2, the composite focal length f of the lens 12 and the crystalline lens 21 decreases, and thus a position where light passing through the crystalline lens 21 forms an image can be moved to the retina 22 side.

As described above, the spot diameter of light reflected by the user's eye 20 on the display device 100 (hereinafter also referred to as a spot diameter s) is larger in the case where the user's eye 20 is not in focus (the spot diameter s1 or the spot diameter s2) than in the case where the user's eye 20 is in focus (the spot diameter s0). That is, it can be said that the spot diameter s of the reflected light on the display device 100 correlates with the distance d between the lens 12 and the user's eye 20 (the crystalline lens 21), and the spot diameter s has the local minimum value (the spot diameter s0) at the distance d where the user's eye 20 is focused.

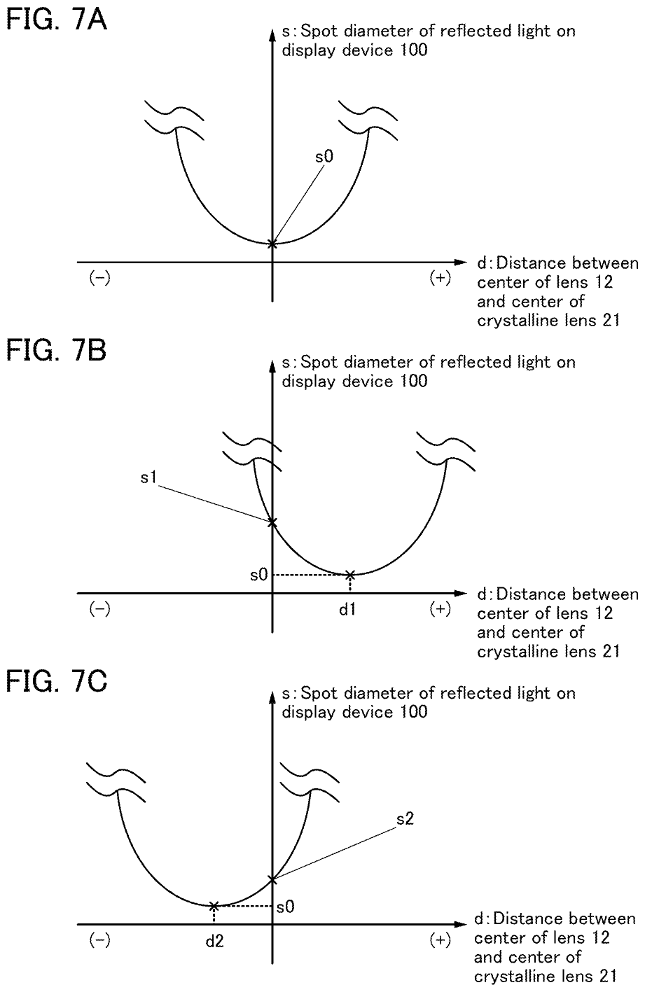

For example, in the case where the eye 20 of the user of the electronic device 10 is focused on the display portion of the display device 100 as illustrated in FIG. 1 and FIG. 2, the spot diameter s on the display device 100 with the user's eye in this state has the local minimum value (the spot diameter s0), and the spot diameter s becomes larger than the spot diameter s0 when the lens 12 is moved to either the + side (the display device 100 side) or the − side (the crystalline lens 21 side) (FIG. 7A).

For example, in the case where the eye 20 of the user of the electronic device 10 is not focused on the display portion of the display device 100 (in the case of the myopic state) as illustrated in FIG. 3 and FIG. 4, the spot diameter s can be made smaller by moving the lens 12 to the + side (the display device 100 side) from the illustrated position (i.e., the position of the lens 12 can be adjusted so that the user's eye 20 can be in focus). FIG. 7B shows that the spot diameter s on the display device 100 changes to the spot diameter s0 from the spot diameter s1 by moving the lens 12 to the + side by a distance d1.

For example, in the case where the eye 20 of the user of the electronic device 10 is not focused on the display portion of the display device 100 (in the case of the hyperopic state) as illustrated in FIG. 5 and FIG. 6, the spot diameter s can be made smaller by moving the lens 12 to the − side (the crystalline lens 21 side) from the illustrated position (i.e., the position of the lens 12 can be adjusted so that the user's eye 20 can be in focus). FIG. 7C shows that the spot diameter s on the display device 100 changes to the spot diameter s0 from the spot diameter s2 by moving the lens 12 to the − side by a distance d2.

In the above manner, the electronic device 10 of one embodiment of the present invention can perform automatic focus adjustment by changing the placing position of the lens 12 as appropriate in accordance with the state of the user's eye (in accordance with the spot diameter s on the display device 100).

### Operation Method Example

A specific example of an operation method in which the optical device 13 included in the electronic device 10 of one embodiment of the present invention automatically adjusts the focus of the user's eye 20 is described below with reference to a flowchart.

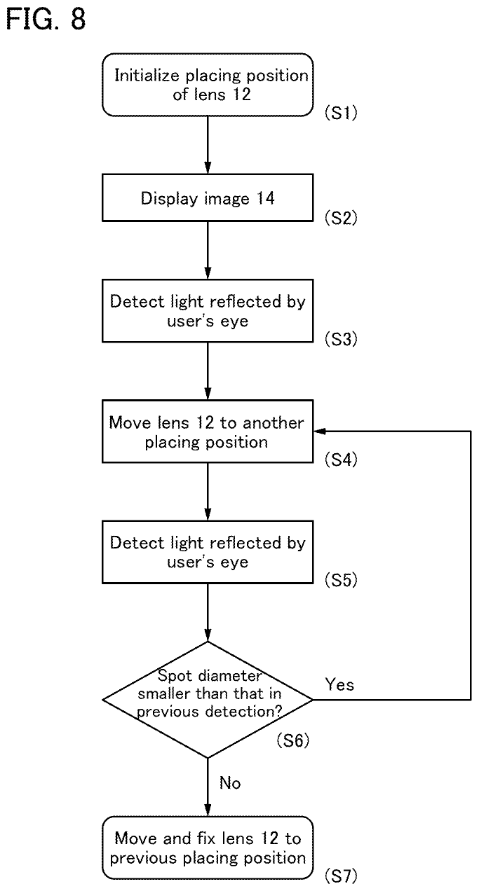

FIG. 8 is a flowchart showing an example of an operation method of the optical device 13 including the display device 100 and the lens 12.

First, in Step S1, the placing position of the lens 12 is initialized. Note that a manufacturer or a user of the electronic device 10 can freely set the initial placing position of the lens 12 illustrated in FIG. 1, FIG. 2, FIG. 3, FIG. 4, FIG. 5, and FIG. 6 between the display device 100 and the user's eye 20. For example, the initial placing position of the lens 12 may be at the position illustrated in FIG. 1, FIG. 2, FIG. 3, FIG. 4, FIG. 5, and FIG. 6, at a position closer to the display device 100 side (+ side), or at a position closer to the crystalline lens 21 side (− side).

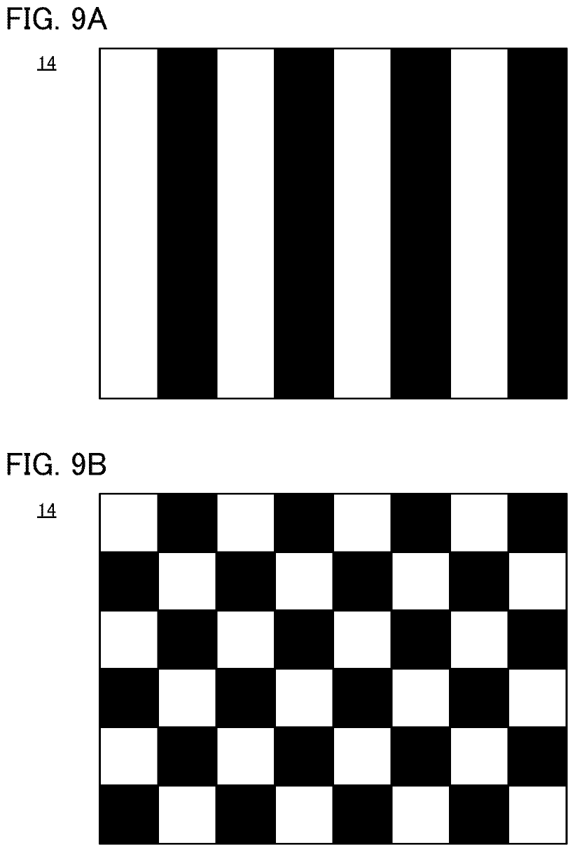

Next, in Step S2, an image 14 is displayed. The image 14 can be used as an image for adjusting the focus of the user's eye 20. For example, a simple image such as an image of stripes (see FIG. 9A) or an image of checkers (see FIG. 9B) may be used as the image 14. Note that the image 14 of one embodiment of the present invention is not limited thereto, and may be a landscape picture of nature or the like or an image of an animal, a person, a building, a vehicle, illustration, or the like.

Furthermore, infrared light may be emitted to the user's eye 20 while the image 14 is displayed. In this case, in addition to a light-emitting device emitting visible light for image display, a light-emitting device emitting infrared light is provided in the display portion of the display device 100 of one embodiment of the present invention.

Note that it is preferable that the image 14 be displayed clearly at first and immediately faded intentionally (this is also referred to as fogging). Thus, the user's eye 20 is inhibited from being focused on the image (thickness adjustment of the crystalline lens 21 is inhibited), whereby the refractive power of the eye can be measured in a normal state (in a relaxing state where the thickness of the crystalline lens 21 is not adjusted).

Next, in Step S3, light (visible light or infrared light) reflected by the user's eye 20 is detected. The display device 100 of one embodiment of the present invention includes a light-receiving device (also referred to as a light-receiving element) in addition to a light-emitting device in the display portion, which will be described in detail in the following embodiment. Thus, the light-receiving device can detect light that is emitted from the light-emitting device and then reflected by the user's eye 20. The electronic device 10 preferably has a function of storing data of reflected light (e.g., the spot diameter and the intensity of reflected light, the modulation transfer function (MTF), and the like) detected by the display device 100 in this step.

Next, in Step S4, the lens 12 is moved to another placing position. The placing position may be more on the display device 100 side (+ side) or on the user's eye 20 side (− side) with respect to the initial placing position. The moving direction and moving distance (moving step) of the lens 12 in Step S4 can be freely set by the manufacturer or the user of the electronic device. The moving direction of the lens 12 in Step S4 is preferably fixed to one direction (from the − side to the + side or from the + side to the − side). In addition, the moving distance of the lens 12 in Step S4 is preferably fixed to a certain value. In this manner, the shape of a curve showing the relation between the distance d and the spot diameter s (see FIGS. 7A to 7C) can be detected more accurately.

Next, in Step S5, light (visible light or infrared light) reflected by the user's eye 20 is detected. Note that as in Step S3, the electronic device 10 preferably has a function of storing data of reflected light (e.g., the spot diameter and the intensity of reflected light, MTF, and the like) detected by the display device 100 in this step.

Next, in Step S6, determined is whether the spot diameter s of the reflected light on the display device 100 detected in Step S5 is smaller than the spot diameter of the reflected light in the previous detection (detection performed immediately before the current detection). When the electronic device 10 has a function of storing data of reflected light detected by the display device 100 in Step S3 and Step S5 as described above, the determination in Step S6 is possible.

Although the spot diameter of reflected light on the display device 100 is used as information for determining whether the user's eye 20 is in focus or not in Step 6, one embodiment of the present invention is not limited thereto. For example, the intensity of reflected light on the display device 100 or MTF may be used as information for determination.

Here, as described with reference to FIGS. 7A to 7C and the like, in the case where the user's eye 20 is focused on the display portion of the display device 100, the spot diameter s of reflected light on the display device 100 has the local minimum value. Thus, in the case where the spot diameter of reflected light detected in Step S5 is larger than the spot diameter of reflected light in the previous detection, it can be determined that the placing position of the lens 12 in the previous detection is the placing position at which the user's eye 20 is in focus. In contrast, in the case where the spot diameter of reflected light detected in Step S5 is smaller than the spot diameter of reflected light in the previous detection, it can be determined that the spot diameter has not reached its local minimum value and the placing position of the lens 12 needs to be further changed.

Therefore, in the case where the spot diameter s of reflected light on the display device 100 detected in Step S5 is determined to be smaller than the spot diameter of reflected light in the previous detection (detection performed immediately before the current detection) in Step 6, the placing position of the lens 12 can be said to be inappropriate and the sequence of Step S4 to Step S6 is repeated.

In contrast, in the case where the spot diameter s of reflected light on the display device 100 detected in Step S5 is determined to be larger than the spot diameter of reflected light in the previous detection (detection performed immediately before the current detection) in Step 6, the placing position of the lens 12 in the previous detection can be said to be the placing position at which the user's eye 20 is in focus; thus, the lens 12 is moved to the placing position in the previous detection to be fixed (Step S7).

Note that the final placing position of the lens 12 may be determined on the basis of the average value of the optimal setting coordinates of the lens 12 detected by performing the sequence of Step S1 to Step S7 a plurality of times.

As described above, the optical device 13 included in the electronic device 10 of one embodiment of the present invention can perform automatic focus adjustment of the user's eye 20. When the optical device 13 adjusts the focus of the user's eye 20 in accordance with the flowchart in FIG. 8 before the display device 100 displays a VR image or an AR image, the user can enjoy the VR image or the AR image displayed after the focus adjustment, in the optimal condition (with the eye focused). Thus, one embodiment of the present invention can provide an electronic device that is easy on a user's eyes and causes less eyestrain and an operation method of the electronic device.

### Structure Example 2

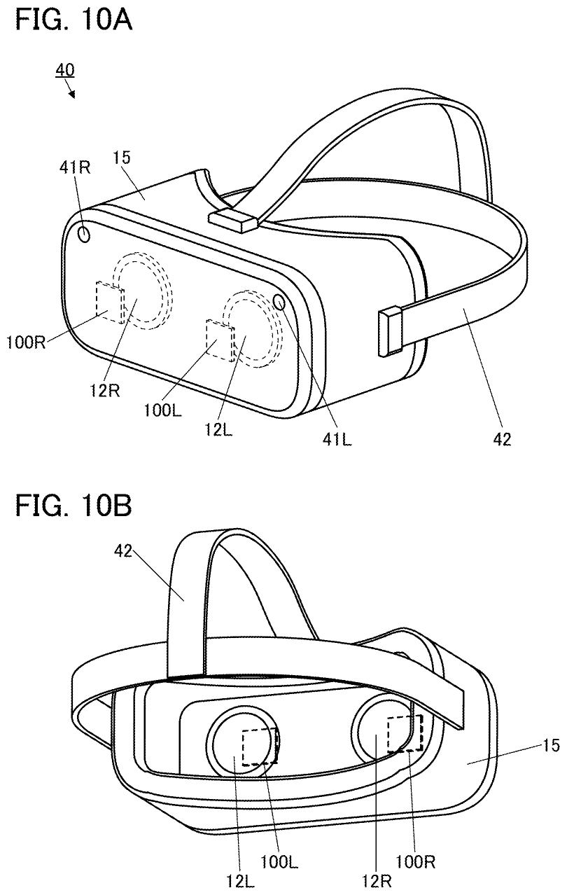

FIGS. 10A and 10B are perspective views of an electronic device 40. FIG. 10A is a perspective view illustrating the front surface, the top surface, and the left side surface of the electronic device 40, and FIG. 10B is a perspective view illustrating the back surface, the bottom surface, and the right side surface of the electronic device 40. The electronic device 40 is what is called a goggle-type head mounted display (HMD), which can be worn on the head.

The electronic device 40 can be used as a VR electronic device. A user wearing the electronic device 40 can watch a three-dimensional video using parallax with different videos for the right eye and the left eye.

The electronic device 40 includes a housing 15 and a wearing tool 42. The housing 15 and the wearing tool 42 are connected to each other, and the wearing tool 42 has a function of fixing the housing 15 to the user's head.

A camera 41R and a camera 41L are provided on the surface of the housing 15. A video taken with the camera 41R and the camera 41L is displayed in real time, whereby the user can know the user's surroundings even when the user is wearing the electronic device 40. Furthermore, a video see-through function can be achieved. A three-dimensional video using parallax can be produced with two or more cameras.

On the side of the housing 15 facing the user, a lens 12R functioning as a right eye lens and a lens 12L functioning as a left eye lens are provided in portions to be in front of the user's eyes. The movable lens 12 illustrated in FIG. 1, FIG. 2, FIG. 3, FIG. 4, FIG. 5, and FIG. 6 can be used as each of the lens 12R and the lens 12L. Furthermore, a display device 100R for displaying an image for the right eye and a display device 100L for displaying an image for the left eye are provided inside the housing 15. It can also be said that the lens 12R (the lens 12L) is positioned on the display portion side of the display device 100R (the display device 100L) in the housing 15. The display device 100 illustrated in FIG. 1, FIG. 2, FIG. 3, FIG. 4, FIG. 5, and FIG. 6 can be used as each of the display device 100R and the display device 100L. In the housing 15, the lens 12R (the lens 12L) is a movable lens that can be moved between the display device 100R (the display device 100L) and the user's eye. That is, it can be said that the housing 15 has a function of changing the distance between the lens 12R (the lens 12L) and the display device 100R (the display device 100L) by moving the lens 12R (the lens 12L).

The display devices 100R and 100L are preferably moved vertically and horizontally in accordance with the positions of the user's eyes, for example. Thus, the display devices 100R and 100L may be fixed to separate frames. The electronic device 40 preferably has a function of moving the lens 12R (the lens 12L) in the same direction by the same distance as the display device 100R (the display device 100L) simultaneously with the movement of the display device 100R (the display device 100L). In other words, the electronic device 40 preferably has a function of finely adjusting the positions of the display device 100R and the lens 12R (the display device 100L and the lens 12L) so that the center portions of the surface of the display device 100R (the display device 100L), the surface of the lens 12R (the lens 12L), and the user's right eye (left eye) are always on one straight line.

A set of the display device 100R and the lens 12R and a set of the display device 100L and the lens 12L in the electronic device 40 each correspond to the optical device 13 illustrated in FIG. 1, FIG. 2, FIG. 3, FIG. 4, FIG. 5, and FIG. 6. Thus, it can be said that the housing 15 of the electronic device 40 includes the optical device 13.

An input terminal and an output terminal may be provided on the surface of the housing 15. To the input terminal, a cable for supplying a video signal from a video output device or the like, power for charging a battery provided in the housing 15, or the like can be connected. The output terminal can function as, for example, an audio output terminal to which earphones, headphones, or the like can be connected. Note that in the case where audio data can be output by wireless communication or sound is output from an external video output device, the audio output terminal is not necessarily provided.

A wireless communication module, a memory module, and the like may be provided inside the housing 15. A content to be watched can be downloaded via wireless communication using the wireless communication module and stored in the memory module. In this manner, the user can watch the downloaded content offline whenever the user likes. The memory module can also store information on reflected light detected by the display device 100 in Step S3, Step S5, and the like in FIG. 8.

At least part of this embodiment can be implemented in combination with any of the other embodiments described in this specification, as appropriate.

### Embodiment 2

In this embodiment, structure examples of a display device that can be used for the electronic device of one embodiment of the present invention are described. Display devices described below as examples can be used as the display device 100 or the like in Embodiment 1.

One embodiment of the present invention is a display device including a light-emitting device and a light-receiving device. The display device includes a pixel including two or more light-emitting devices emitting light of different colors and a pixel including a light-receiving device receiving external light. Such pixels can also be referred to as subpixels.

The light-emitting device includes a pair of electrodes and an EL layer therebetween. The light-emitting device is preferably an organic electroluminescent device (organic EL device). In the case where two or more light-emitting devices emit light of different colors, the two or more light-emitting devices include EL layers containing different light-emitting materials. For example, when three kinds of light-emitting devices emitting red (R), green (G), and blue (B) light (visible light) are included, a full-color display device can be obtained. In the case where two or more light-emitting devices emit light of the same color, the two or more light-emitting devices include EL layers containing the same light-emitting material. Alternatively, a light-emitting device may include an EL layer containing a light-emitting material emitting infrared light (IR) instead of an EL layer containing a light-emitting material emitting visible light.

The light-receiving device includes a pair of electrodes and an active layer that functions as a photoelectric conversion layer therebetween. It is preferable to use an organic photodiode containing an organic compound as the light-receiving device. With the use of an organic photodiode as the light-receiving device, both the light-receiving device and the light-emitting device can be formed on the same substrate in the case where an organic EL device is used as the light-emitting device. The light-receiving device can detect one or both of visible light and infrared light.

For example, a detection target is irradiated with light (visible light or infrared light) emitted from the light-emitting device, and the light which is reflected by the detection target can be detected by the light-receiving device. When the detection target is an eye of a user of the electronic device of one embodiment of the present invention, for example, the display device included in the electronic device of one embodiment of the present invention can measure the spot diameter of light reflected by the user's eye. Since the spot diameter depends on the refractive power and the curvature radius of the user's eye, the display device included in the electronic device of one embodiment of the present invention can determine whether the user's eye is focused on the display portion of the display device.

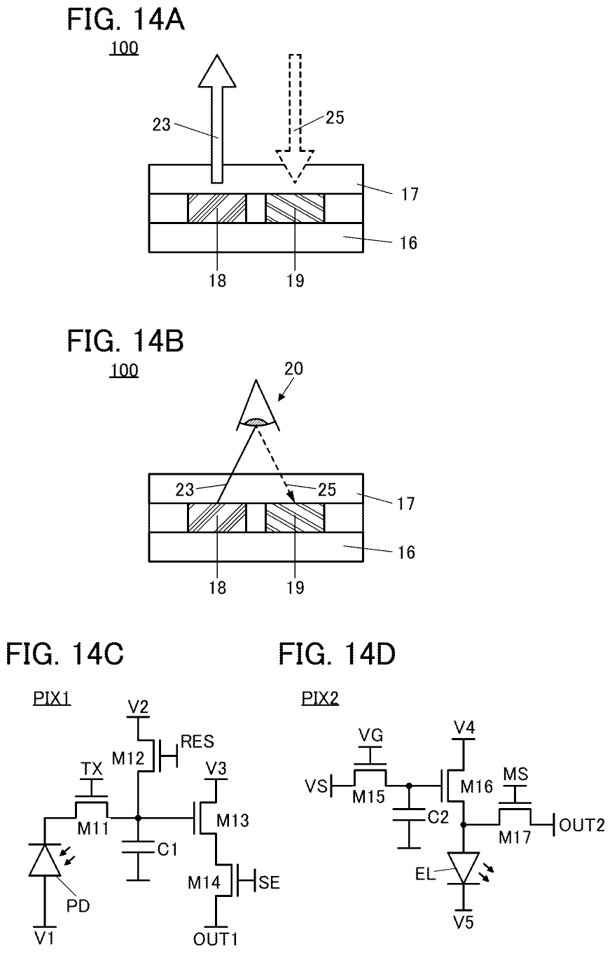

FIG. 14A illustrates a structure example of the display device 100 included in the electronic device of one embodiment of the present invention. The display device 100 includes a substrate 16 and a substrate 17, and a light-emitting device 18 and a light-receiving device 19 are provided between the substrate 16 and the substrate 17.

The light-emitting device 18 has a function of emitting light 23. The light 23 can be visible light or infrared light.

The light-receiving device 19 has a function of detecting light 25 with which the light-receiving device 19 is irradiated. The light 25 can be visible light or infrared light.

A photoelectric conversion element (also referred to as a photoelectric conversion device) that detects the incident light 25 and generates electric charge can be used as the light-receiving device 19. The amount of electric charge generated by the light-receiving device 19 depends on the amount of light entering the light-receiving device 19. As the light-receiving device 19, a PN photodiode or a PIN photodiode can be used, for example.

It is preferable to use an organic photodiode containing an organic compound in a photoelectric conversion layer as the light-receiving device 19. An organic photodiode is easily made thin and lightweight and easily has a large area. Moreover, an organic photodiode has high degree of freedom for shape and design and thus can be applied to a variety of light-receiving devices. Alternatively, a photodiode containing amorphous silicon, crystalline silicon (e.g., single crystal silicon, polycrystalline silicon, or microcrystalline silicon), a metal oxide, or the like can be used as the light-receiving device 19.

A photodiode containing an appropriate material as an organic compound in a photoelectric conversion layer can have sensitivity to light ranging from ultraviolet light to infrared light. A photodiode containing amorphous silicon in a photoelectric conversion layer has sensitivity mainly to visible light, and a photodiode containing crystalline silicon in a photoelectric conversion layer has sensitivity to light ranging from visible light to infrared light. Since a metal oxide has a wide band gap, a photodiode containing a metal oxide in a photoelectric conversion layer has high sensitivity to light having a higher energy than visible light. Note that an In-M-Zn oxide (the element M is one or more kinds selected from aluminum, gallium, yttrium, tin, titanium, and the like) can be used as the metal oxide, for example.

For example, in the display device 100, the light 23 can be emitted from the light-emitting device 18 to the detection target and the light-receiving device 19 can detect the light reflected by the detection target as the light 25.

FIG. 14B illustrates an example of a function of the display device 100 included in the electronic device of one embodiment of the present invention. In FIG. 14B, the eye 20 is the detection target. The eye 20 can be an eye of a user of the electronic device including the display device 100, for example.

In the example illustrated in FIG. 14B, the eye 20 is irradiated with the light 23 emitted from the light-emitting device 18 and the light-receiving device 19 detects the light reflected by the eye 20 as the light 25. For example, in the case where the light 23 is parallel light having the constant (known) spot diameter, the refractive power and the curvature radius of the eye 20 can be measured by detecting the spot diameter of the light 25 on a light-receiving surface of the light-receiving device 19. In other words, whether the eye 20 is focused on the display portion of the display device 100 can be determined.

FIG. 14C shows an example of a pixel circuit of a subpixel including a light-receiving device. FIG. 14D shows an example of a pixel circuit of a subpixel including a light-emitting device.

A pixel circuit PIX1 illustrated in FIG. 14C includes a light-receiving device PD, a transistor M11, a transistor M12, a transistor M13, a transistor M14, and a capacitor C1. Here, a photodiode is used as an example of the light-receiving device PD.

An anode of the light-receiving device PD is electrically connected to a wiring V1, and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C1, one of a source and a drain of the transistor M12, and a gate of the transistor M13. A gate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE, and the other of the source and the drain of the transistor M14 is electrically connected to a wiring OUT1.

A constant potential is supplied to the wiring V1, the wiring V2, and the wiring V3. When the light-receiving device PD is driven with a reverse bias, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with a current flowing through the light-receiving device PD. The transistor M13 functions as an amplifier transistor for outputting a signal corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 14D includes a light-emitting device EL, a transistor M15, a transistor M16, a transistor M17, and a capacitor C2. Here, a light-emitting diode is used as an example of the light-emitting device EL. In particular, an organic EL device is preferably used as the light-emitting device EL.

A gate of the transistor M15 is electrically connected to a wiring VG, one of a source and a drain of the transistor M15 is electrically connected to a wiring VS, and the other of the source and the drain of the transistor M15 is electrically connected to one electrode of the capacitor C2 and a gate of the transistor M16. One of a source and a drain of the transistor M16 is electrically connected to a wiring V4, and the other of the source and the drain of the transistor M16 is electrically connected to an anode of the light-emitting device EL and one of a source and a drain of the transistor M17. A gate of the transistor M17 is electrically connected to a wiring MS, and the other of the source and the drain of the transistor M17 is electrically connected to a wiring OUT2. A cathode of the light-emitting device EL is electrically connected to a wiring V5.

A constant potential is supplied to the wiring V4 and the wiring V5. The anode of the light-emitting device EL can be set to a high potential, and the cathode can be set to a lower potential than the anode. The transistor M15 is controlled by a signal supplied to the wiring VG and functions as a selection transistor for controlling a selection state of the pixel circuit PIX2. The transistor M16 functions as a driving transistor that controls a current flowing through the light-emitting device EL in accordance with a potential supplied to the gate of the transistor M16. When the transistor M15 is on, a potential supplied to the wiring VS is supplied to the gate of the transistor M16, and the luminance of the light-emitting device EL can be controlled in accordance with the potential. The transistor M17 is controlled by a signal supplied to the wiring MS and has a function of outputting a potential between the transistor M16 and the light-emitting device EL to the outside through the wiring OUT2.

Here, transistors in which a metal oxide (an oxide semiconductor) is used in a semiconductor layer where a channel is formed (hereinafter, such transistors are also referred to as OS transistors) are preferably used as the transistors M11, M12, M13, and M14 included in the pixel circuit PIX1 and the transistors M15, M16, and M17 included in the pixel circuit PIX2.

A transistor using a metal oxide having a wider band gap and a lower carrier density than silicon achieves an extremely low off-state current. Therefore, owing to the low off-state current, charge accumulated in a capacitor that is connected in series to the transistor can be retained for a long time. Hence, it is particularly preferable to use transistors containing an oxide semiconductor as the transistors M11, M12, and M15 each of which is connected in series with the capacitor C1 or the capacitor C2. When the other transistors also include an oxide semiconductor, the manufacturing cost can be reduced.

For example, the off-state current per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor (a transistor using silicon in a semiconductor layer where a channel is formed) at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

Si transistors can also be used as the transistors M11 to M17. It is particularly preferable to use silicon with high crystallinity such as single crystal silicon or polycrystalline silicon in a semiconductor layer where a channel is formed because a transistor can have high field-effect mobility and operate at higher speed.

Alternatively, a transistor including an oxide semiconductor (an OS transistor) may be used as at least one of the transistors M11 to M17, and transistors including silicon (Si transistors) may be used as the other transistors.

Although FIG. 14C and FIG. 14D illustrate examples in which the transistors M11 to M17 each include three terminals (a source terminal, a gate terminal, and a drain terminal), one embodiment of the present invention is not limited thereto. For example, the transistors M11 to M17 may each include four terminals (a source terminal, a first gate terminal, a second gate terminal facing the first gate terminal, and a drain terminal).

Although n-channel transistors are shown in FIGS. 14C and 14D, p-channel transistors can alternatively be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including the transistor and/or the capacitor are preferably provided to overlap with the light-receiving device PD or the light-emitting device EL. Thus, the effective area of each pixel circuit can be reduced, and a high-resolution light-receiving portion or display portion can be achieved.

To increase the luminance of the light-emitting device EL included in the pixel circuit, the amount of current fed through the light-emitting device EL needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Thus, with the use of an OS transistor as the driving transistor included in the pixel circuit, the amount of current flowing through the light-emitting device can be increased and the luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Therefore, the number of gray levels in the pixel circuit can be increased.

Regarding saturation characteristics of current flowing when transistors operate in a saturation region, even in the case where the source-drain voltage of an OS transistor increases gradually, a more stable constant current (saturation current) can be fed through the OS transistor than through a Si transistor. Thus, by using an OS transistor as the driving transistor, a stable current can be fed through light-emitting devices that contain an EL material even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, the use of an OS transistor as the driving transistor included in the pixel circuit enables “inhibition of black blurring”, “an increase in luminance”, “an increase in gray levels”, “inhibition of variations in the luminance of the light-emitting device”, and the like.

The refresh rate of the display device of one embodiment of the present invention can be variable. For example, the refresh rate is adjusted (in the range from 0.01 Hz to 240 Hz, for example) in accordance with contents displayed on the display device, whereby power consumption can be reduced. Moreover, driving with a lowered refresh rate that enables the power consumption of the display device may be referred to as idling stop (IDS) driving.

Hereinafter, a specific structure example of the display device of one embodiment of the present invention is described.

As described above, the display device of one embodiment of the present invention includes a plurality of light-emitting devices emitting light of different colors. In the case of manufacturing such a display device, at least layers (light-emitting layers) containing light-emitting materials different in emission color each need to be formed in an island shape. In a known method for separately forming part or the whole of an EL layer, an island-shaped organic film is formed by an evaporation method using a shadow mask such as a metal mask. However, this method has difficulty in achieving high resolution and a high aperture ratio of a display device because in this method, a deviation from the designed shape and position of the island-shaped organic film is caused by various influences such as the low accuracy of the metal mask position, the positional deviation between the metal mask and a substrate, a warp of the metal mask, and the vapor-scattering-induced expansion of the outline of the formed film. In addition, the outline of a layer may blur during vapor deposition, whereby the thickness of its end portion may be small. That is, the thickness of an island-shaped light-emitting layer may vary from area to area. In the case of manufacturing a display device with a large size, high definition, or high resolution, the manufacturing yield might be reduced because of low dimensional accuracy of the metal mask and deformation due to heat or the like. Thus, a measure has been taken for pseudo improvement in resolution (also referred to pixel density). As a specific measure, a unique pixel arrangement such as a PenTile pattern has been employed.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In one embodiment of the present invention, fine patterning of an EL layer is performed by a photolithography method without a shadow mask such as a fine metal mask (FMM). With the patterning, a high-resolution display device with a high aperture ratio, which has been difficult to achieve, can be fabricated. Moreover, EL layers can be formed separately, enabling the display device to perform extremely clear display with high contrast and high display quality. Note that fine patterning of an EL layer may be performed using both a metal mask and a photolithography method, for example.

Part or the whole of the EL layer can be physically partitioned, inhibiting a leakage current flowing between adjacent light-emitting devices through a layer (also referred to as a common layer) shared by the light-emitting devices. This can prevent crosstalk due to unintended light emission, so that a display device with extremely high contrast can be obtained. Specifically, a display device having high current efficiency at low luminance can be obtained.

A display device of one embodiment of the present invention can also be obtained by combining white-light-emitting devices with a color filter. In that case, the light-emitting devices having the same structure can be provided in pixels (subpixels) emitting light of different colors, allowing all the layers to be common layers. Furthermore, part or the whole of the EL layer may be partitioned by a photolithography method, which inhibits a leakage current from flowing through the common layers to achieve a display device with high contrast. In particular, when an element has a tandem structure in which a plurality of light-emitting layers are stacked with a highly conductive intermediate layer therebetween (the details of the tandem structure is to be described later), a leakage current through the intermediate layer can be effectively prevented, achieving a display device with high luminance, high resolution, and high contrast.

In the case where the EL layer is processed by a photolithography method, part of the light-emitting layer is sometimes exposed to cause deterioration. Thus, an insulating layer covering at least a side surface of the island-shaped light-emitting layer is preferably provided. The insulating layer may cover part of a top surface of the island-shaped EL layer. For the insulating layer, a material having a barrier property against water and oxygen is preferably used. For example, an inorganic insulating film that is less likely to diffuse water and oxygen can be used. Thus, the deterioration of the EL layer is inhibited, and a highly reliable display device can be achieved.

Between two light-emitting devices that are adjacent to each other, there is a region (depression) where the EL layers of the light-emitting devices are not provided. In the case where the depression is covered with a common electrode or with a common electrode and a common layer, the common electrode might be disconnected (or “step-cut”) by a step at an end portion of the EL layer, thereby causing insulation of the common electrode over the EL layer. In view of this, the local gap between the two adjacent light-emitting devices is preferably filled with a resin layer (also referred to as local filling planarization, or LFP) serving as a planarization film. This structure can inhibit a step-cut of the common layer or the common electrode, making it possible to obtain a highly reliable display device.

More specific structure examples of the display device of one embodiment of the present invention are described below with reference to drawings.

### Structure Example 1

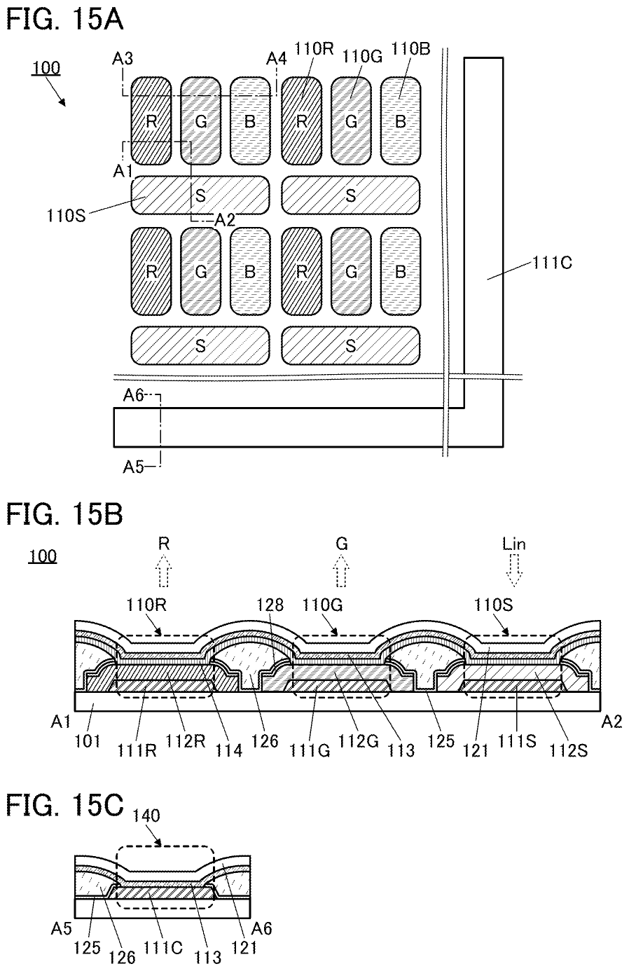

FIG. 15A is a schematic plan view of the display device 100 of one embodiment of the present invention. The display device 100 includes, over a substrate 101 (see FIG. 15B), a plurality of light-emitting devices 110R emitting red light, a plurality of light-emitting devices 110G emitting green light, a plurality of light-emitting devices 110B emitting blue light, and a plurality of light-receiving devices 110S receiving visible light or infrared light. In FIG. 15A, light-emitting regions of the light-emitting devices are denoted by R, G, and B and light-receiving regions of the light-receiving devices are denoted by S to easily differentiate the light-emitting devices and the light-receiving devices.

As each of the light-emitting devices 110R, 110G, and 110B, an organic light-emitting diode (OLED) or a quantum-dot light-emitting diode (QLED) is preferably used, for example. Examples of a light-emitting substance contained in the light-emitting device include a substance exhibiting fluorescence (fluorescent material), a substance exhibiting phosphorescence (phosphorescent material), an inorganic compound (e.g., a quantum dot material), and a substance exhibiting thermally activated delayed fluorescence (a thermally activated delayed fluorescent (TADF) material).

FIG. 15A also illustrates a connection electrode 111C that is electrically connected to a common electrode 113 (see FIG. 15B and FIG. 15C). The connection electrode 111C is supplied with a potential (e.g., an anode potential or a cathode potential) that is to be supplied to the common electrode 113. The connection electrode 111C is provided outside a display region where the light-emitting devices 110R and the like are arranged.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular planar shape, a planar shape of the connection electrode 111C can be a band shape (a rectangular shape), an L shape, a square bracket shape, a quadrangular shape, or the like.

As the light-receiving device, a PN photodiode or a PIN photodiode can be used, for example. The light-receiving device functions as a photoelectric conversion element that detects light incident on the light-receiving device and generates electric charge. The amount of electric charge generated by the light-receiving device depends on the amount of light entering the light-receiving device.

The light-receiving device can detect one or both of visible light and infrared light. In the case of detecting visible light, for example, one or more of blue light, violet light, bluish violet light, green light, yellowish green light, yellow light, orange light, red light, and the like can be detected. Infrared light is preferably detected because an object can be detected even in a dark environment.

It is particularly preferable to use an organic photodiode including a layer containing an organic compound as the light-receiving device. An organic photodiode, which is easily made thin, lightweight, and large in area and has a high degree of freedom for shape and design, can be used in a variety of display devices.

In one embodiment of the present invention, an organic EL device is used as the light-emitting device, and an organic photodiode is used as the light-receiving device. The organic EL device and the organic photodiode can be formed over one substrate. Thus, the organic photodiode can be incorporated in a display device including the organic EL device.

The light-receiving device is driven by application of reverse bias between the pixel electrode and the common electrode, whereby light entering the light-receiving device can be detected and electric charge can be generated and extracted as a current.

A manufacturing method similar to that of the light-emitting device can be employed for the light-receiving device. An island-shaped active layer (also referred to as a photoelectric conversion layer) included in the light-receiving device is formed by processing a film to be the active layer and formed on the entire surface, not by using a fine metal mask; thus, the island-shaped active layer can have a uniform thickness. Moreover, providing a protective layer (also referred to as a mask layer or a sacrifice layer) over the active layer can reduce damage to the active layer in the manufacturing process of the display device, resulting in an improvement in reliability of the light-receiving device.

Embodiment 4 can be referred to for the details of the structures and the materials of the light-emitting devices and the light-receiving device.

Note that FIG. 15A illustrates an example in which the aperture ratio (also referred to as the size, or the size of the light-receiving region) of the light-receiving device 110S is higher than the aperture ratios (also referred to as the sizes, or the sizes of the light-emitting regions) of the light-emitting devices 110R, 110G, and 110B, one embodiment of the present invention is not limited thereto. The aperture ratios of the light-emitting devices 110R, 110G, and 110B, and the light-receiving device 110S can each be determined as appropriate. The light-emitting devices 110R, 110G, and 110B, and the light-receiving device 110S may have different aperture ratios, or two or more of them may have the same or substantially the same aperture ratio.

The light-receiving device 110S may have a higher aperture ratio than at least one of the light-emitting devices 110R, 110G, and 110B. A wide light-receiving area of the light-receiving device 110S can make it easy to detect a target in some cases. For example, depending on the resolution of the display device, the circuit structure of the subpixel, and the like, the aperture ratio of the light-receiving device 110S is higher than the aperture ratios of the light-emitting devices 110R, 110G, and 110B in some cases.

The light-receiving device 110S may have a lower aperture ratio than at least one of the light-emitting devices 110R, 110G, and 110B. When the light-receiving device 110S has a small light-receiving area, an image capturing area is narrowed and it is possible to inhibit blur from occurring in the captured image being displayed and to increase the definition. Accordingly, high-resolution or high-definition image capturing can be performed, which is preferable.

As described above, the light-receiving device 110S can have a detection wavelength, a resolution, and an aperture ratio that are suitable for the intended use.

FIGS. 15B and 15C are schematic cross-sectional views taken along dashed-dotted line A1-A2 and dashed-dotted line A5-A6 in FIG. 15A. FIG. 15B is a schematic cross-sectional view of the light-emitting device 110R, the light-emitting device 110G, and the light-receiving device 110S, and FIG. 15C is a schematic cross-sectional view of a connection portion 140 to which the connection electrode 111C and the common electrode 113 are connected.

FIG. 15B illustrates an example in which the light-emitting device 110R and the light-emitting device 110G emit light to a side opposite to the substrate 101 and light is incident on the light-receiving device 110S from the side opposite to the substrate 101 (see light R, light G, and light Lin).

The light-emitting device 110R includes a pixel electrode 111R, an organic layer 112R, a common layer 114, and the common electrode 113. The light-emitting device 110G includes a pixel electrode 111G, an organic layer 112G, the common layer 114, and the common electrode 113. The light-emitting device 110B includes a pixel electrode 111B (not illustrated), an organic layer 112B (not illustrated), the common layer 114, and the common electrode 113. The light-receiving device 110S includes a pixel electrode 111S, an organic layer 112S, the common layer 114, and the common electrode 113. The light-emitting devices 110R, 110G, and 110B and the light-receiving device 110S include the common layer 114 and the common electrode 113 in common.

The organic layer 112R of the light-emitting device 110R contains at least a light-emitting organic compound emitting red light. The organic layer 112G of the light-emitting device 110G contains at least a light-emitting organic compound emitting green light. The organic layer 112B of the light-emitting device 110B contains at least a light-emitting organic compound emitting blue light. Each of the organic layers 112R, 112G, and 112B can also be referred to as an EL layer, and includes at least a layer containing a light-emitting organic compound (a light-emitting layer).

Hereafter, the term “light-emitting device 110” is sometimes used to describe matters common to the light-emitting devices 110R, 110G, and 110B. Similarly, the term “pixel electrode 111” is sometimes used to describe matters common to the pixel electrodes 111R, 111G, 111B, and 111S.

The organic layer 112R, the organic layer 112G, the organic layer 112B, and the common layer 114 can each independently include one or more of an electron-injection layer, an electron-transport layer, a hole-injection layer, and a hole-transport layer. For example, the organic layer 112 can include a hole-injection layer, a hole-transport layer, a light-emitting layer, and an electron-transport layer that are stacked from the pixel electrode 111 side, and the common layer 114 can include an electron-injection layer.

The organic layer 112S included in the light-receiving device 110S contains at least an organic compound that converts (photoelectrically converts) light incident on the light-receiving device 110S into electric charge. The organic layer 112S includes at least an active layer, and can include one or more of a hole-transport layer, an electron-transport layer, a hole-blocking layer, and an electron-blocking layer.

The organic layer 112S is provided in the light-receiving device 110S, which is not provided in the light-emitting devices (the light-emitting devices 110R, 110G, and 110B). Note that a layer other than the active layer included in the organic layer 112S includes the same material as a layer other than the light-emitting layer included in the organic layers 112R, 112G, and 112B in some cases. Meanwhile, the common layer 114 is a continuous layer shared by the light-emitting device and the light-receiving device.

Here, a layer shared by the light-receiving device and the light-emitting device may have a different function depending on which device the layer is in. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-receiving device and the light-emitting device. A hole-transport layer functions as a hole-transport layer in both the light-emitting device and the light-receiving device, and an electron-transport layer functions as an electron-transport layer in both the light-emitting device and the light-receiving device.

The pixel electrode 111R, the pixel electrode 111G, and the pixel electrode 111B are provided for the corresponding light-emitting devices, and the pixel electrode 111S is provided for the light-receiving device. Each of the common electrode 113 and the common layer 114 is provided as a continuous layer shared by the light-emitting devices and the light-receiving device. A conductive film that has a property of transmitting visible light is used for either the respective pixel electrodes or the common electrode 113, and a reflective conductive film is used for the other. When the respective pixel electrodes are light-transmitting electrodes and the common electrode 113 is a reflective electrode, a bottom-emission display device is obtained. When the respective pixel electrodes are reflective electrodes and the common electrode 113 is a light-transmitting electrode, a top-emission display device is obtained. Note that when both the respective pixel electrodes and the common electrode 113 transmit light, a dual-emission display device can be obtained.

A protective layer 121 is provided over the common electrode 113 so as to cover the light-emitting devices 110R, 110G, and 110B and the light-receiving device 110S. The protective layer 121 has a function of preventing diffusion of impurities such as water into the light-emitting devices and the light-receiving device from the above.

The pixel electrode 111 preferably has an end portion with a tapered shape. In the case where the pixel electrode 111 has an end portion with a tapered shape, the organic layer 112 (the organic layers 112R, 112G, 112B, and 112S) provided along the end portion of the pixel electrode 111 can also have a tapered shape. When the end portion of the pixel electrode 111 has a tapered shape, coverage with the organic layer 112 provided to cover the end portion of the pixel electrode 111 can be improved. Furthermore, when the side surface of the pixel electrode 111 is tapered, a material (such as dust or particles) in the manufacturing process of the display device is easily removed by processing such as cleaning, which is preferable.

Note that in this specification and the like, a tapered shape refers to a shape such that at least part of a side surface of a component is inclined with respect to a substrate surface or a formation surface of the component. For example, a tapered shape refers to including a region where the angle between the inclined side surface and the substrate surface or the formation surface of the component (such an angle is also referred to as a taper angle) is less than 90°.

The organic layer 112 has an island shape as a result of processing by a photolithography method. Thus, the angle formed between a top surface and a side surface of an end portion of the organic layer 112 is approximately 90°. By contrast, an organic film formed using an FMM or the like has a thickness that tends to gradually decrease with decreasing distance to an end portion, and has a top surface forming a slope in an area extending greater than or equal to 1 μm and less than or equal to 10 μm from the end portion, for example; thus, such an organic film sometimes has a shape whose top surface and side surface cannot be easily distinguished from each other.

An insulating layer 125, a resin layer 126, and a layer 128 are provided between two adjacent light-emitting devices and between a light-emitting device and a light-receiving device that are adjacent to each other.

The side surfaces of the organic layers 112 of two adjacent light-emitting devices, or a light-emitting device and a light-receiving device that are adjacent to each other are provided to face each other with the resin layer 126 therebetween. The resin layer 126 is positioned between the two adjacent light-emitting devices and between the light-emitting device and the light-receiving device that are adjacent to each other so as to fill the region between the end portions of their organic layers 112 and the region between the two organic layers 112. The resin layer 126 has a top surface with a smooth convex shape. The top surface of the resin layer 126 is covered with the common layer 114 and the common electrode 113.

The resin layer 126 functions as a planarization film that fills a gap between two adjacent light-emitting devices and between a light-emitting device and a light-receiving device that are adjacent to each other. Providing the resin layer 126 can prevent a phenomenon in which the common electrode 113 is divided by a gap at the end portion of the organic layer 112 (also referred to as step-cut) from occurring and the common electrode 113 over the organic layer 112 from being insulated. The resin layer 126 can also be referred to as an LFP layer.

An insulating layer containing an organic material can be suitably used as the resin layer 126. Examples of materials used for the resin layer 126 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The resin layer 126 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, the resin layer 126 can be formed using a resin that can be used as a color filter transmitting red, blue, or green light and absorbing light of the other colors; or a resin that contains carbon black as a pigment and functions as a black matrix.

The insulating layer 125 is provided to be in contact with the side surface of the organic layer 112 and to cover an upper end portion of the organic layer 112. Part of the insulating layer 125 is in contact with the top surface of the substrate 101.

The insulating layer 125 is positioned between the resin layer 126 and the organic layer 112 to function as a protective film for preventing contact between the resin layer 126 and the organic layer 112. In the case of bringing the resin layer 126 into contact with the organic layer 112, the organic layer 112 might be dissolved by an organic solvent or the like used in formation of the resin layer 126. In view of this, the insulating layer 125 is provided between the organic layer 112 and the resin layer 126 to protect the side surface of the organic layer 112.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an atomic layer deposition (ALD) method is used for the insulating layer 125, the insulating layer 125 has a small number of pin holes and excels in a function of protecting the EL layer.

Note that in this specification and the like, oxynitride refers to a material in which an oxygen content is higher than a nitrogen content, and nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The insulating layer 125 can be formed by a sputtering method, a chemical vapor deposition (CVD) method, a pulsed layer deposition (PLD) method, an ALD method, or the like. The insulating layer 125 is preferably formed by an ALD method achieving good coverage.

Between the insulating layer 125 and the resin layer 126, a reflective film (e.g., a metal film containing one or more of silver, palladium, copper, titanium, aluminum, and the like) may be provided to reflect the light that is emitted from the light-emitting layer. In this case, the light extraction efficiency can be increased.

Part of a protective layer for protecting the organic layer 112 during etching of the organic layer 112 survives the etching to become the layer 128. For the layer 128, the material that can be used for the insulating layer 125 can be used. Particularly, the layer 128 and the insulating layer 125 are preferably formed with the same material, in which case an apparatus or the like for processing can be used in common.

In particular, a metal oxide film such as an aluminum oxide film or a hafnium oxide film and an inorganic insulating film such as a silicon oxide film which are formed by an ALD method have a small number of pinholes, and thus excel in the function of protecting the EL layer and are preferably used for the insulating layer 125 and the layer 128.

The protective layer 121 can have, for example, a single-layer structure or a stacked-layer structure including at least an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

As the protective layer 121, a stacked film of an inorganic insulating film and an organic insulating film can be used. For example, a structure in which an organic insulating film is sandwiched between a pair of inorganic insulating films is preferable. Furthermore, it is preferred that the organic insulating film function as a planarization film. With this structure, a top surface of the organic insulating film can be flat, and accordingly, coverage of a formation surface with the inorganic insulating film over the organic insulating film is improved, leading to an improvement in barrier property of the protective layer 121. Moreover, since a top surface of the protective layer 121 is flat, a preferable effect can be obtained; when a component (e.g., a color filter, a lens array, or the like) is provided above the protective layer 121, the component is less affected by an uneven shape caused by the lower structure.

FIG. 15C illustrates the connection portion 140 in which the connection electrode 111C is electrically connected to the common electrode 113. In the connection portion 140, an opening portion is provided in the insulating layer 125 and the resin layer 126 over the connection electrode 111C. In the opening portion, the connection electrode 111C and the common electrode 113 are electrically connected to each other.

Although FIG. 15C illustrates the connection portion 140 in which the connection electrode 111C and the common electrode 113 are electrically connected to each other, the common electrode 113 may be provided over the connection electrode 111C with the common layer 114 therebetween. Particularly in the case of the common layer 114 that includes a carrier-injection layer (a hole-injection layer or an electron-injection layer), for example, the common layer 114 can be formed to be thin using a material with sufficiently low electrical resistivity and thus can be in the connection portion 140 almost without causing any problem. Accordingly, the common electrode 113 and the common layer 114 can be formed using the same shielding mask, whereby manufacturing costs can be reduced.

### Structure Example 2

A display device partly different from Structure example 1 is described below. Note that Structure example 1 is referred to for the same portions and the description is skipped here in some cases.

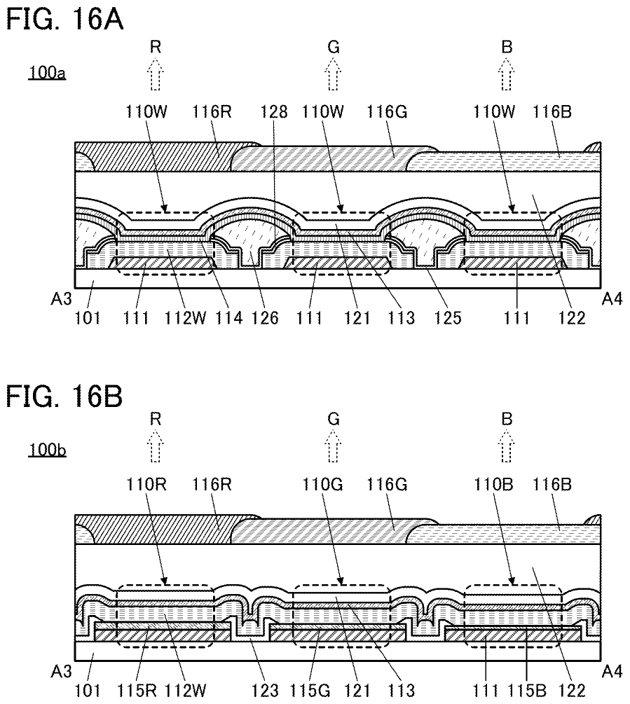

FIG. 16A is a schematic cross-sectional view of a display device 100a (taken along dashed-dotted line A3-A4 in FIG. 15A). The display device 100a is different from the display device 100 mainly in the structure of the light-emitting device and including a coloring layer (also referred to as a color filter).

The display device 100a includes a light-emitting device 110W emitting white light. The light-emitting device 110W includes the pixel electrode 111, an organic layer 112W, the common layer 114, and the common electrode 113. The organic layer 112W emits white light. For example, the organic layer 112W can contain two kinds of light-emitting materials that emit light of complementary colors, or three or more kinds of light-emitting materials that emit light of colors which are combined to be white. For example, the organic layer 112W can contain a light-emitting organic compound emitting red light, a light-emitting organic compound emitting green light, and a light-emitting organic compound emitting blue light. Alternatively, the organic layer 112W may contain a light-emitting organic compound emitting blue light and a light-emitting organic compound emitting yellow light.

The organic layer 112W is divided between the two adjacent light-emitting devices 110W. Thus, a leakage current that might flow between the adjacent light-emitting devices 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 is a formation surface on which the coloring layer 116R, the coloring layer 116G, and the coloring layer 116B are formed. Thus, with a flat top surface of the insulating layer 122, the thickness of the coloring layer 116R or the like can be uniform and color purity of light extracted from each light-emitting device can be increased. Note that if the thickness of the coloring layer 116R or the like is not uniform, the amount of light absorption varies depending on a region in the coloring layer 116R or the like, which might decrease color purity of light extracted from each light-emitting device.

### Structure Example 3

FIG. 16B is a schematic cross-sectional view of a display device 100b (taken along dashed-dotted line A3-A4 in FIG. 15A).

The light-emitting device 110R includes the pixel electrode 111, a conductive layer 115R, the organic layer 112W, and the common electrode 113. The light-emitting device 110G includes the pixel electrode 111, a conductive layer 115G, the organic layer 112W, and the common electrode 113. The light-emitting device 110B includes the pixel electrode 111, a conductive layer 115B, the organic layer 112W, and the common electrode 113. The conductive layers 115R, 115G, and 115B each have a light-transmitting property and function as an optical adjustment layer.

A film reflecting visible light is used for the pixel electrode 111 and a film having a property of reflecting and transmitting visible light is used for the common electrode 113, whereby a micro optical resonator (microcavity) structure can be obtained. In this case, by adjusting the thicknesses of the conductive layers 115R, 115G, and 115B to obtain optimal optical path lengths, light with different wavelengths and increased intensities can be extracted from the light-emitting devices 110R, 110G, and 110B even when the organic layer 112W emitting white light is used.

Furthermore, the coloring layers 116R, 116G, and 116B are provided on the optical paths of the light-emitting devices 110R, 110G, and 110B, respectively, whereby light with high color purity can be extracted from each light-emitting device.

An insulating layer 123 that covers end portions of the pixel electrode 111 and the optical adjustment layer 115 (the conductive layers 115R, 115G, and 115B) is provided. The insulating layer 123 preferably has an end portion with a tapered shape. The insulating layer 123 can increase coverage with the organic layer 112W, the common electrode 113, the protective layer 121, and the like provided over the insulating layer 123.

The organic layer 112W and the common electrode 113 are each provided as one continuous film shared by the light-emitting devices. Such a structure is preferable because the manufacturing process of the display device can be greatly simplified.

Here, the end portion of the pixel electrode 111 is preferably substantially perpendicular to the top surface of the substrate 101. In this manner, a steep portion can be formed on the surface of the insulating layer 123, and thus part of the organic layer 112W covering the steep portion can have a small thickness or part of the organic layer 112W can be separated. Accordingly, a leakage current generated between adjacent light-emitting devices through the organic layer 112W can be inhibited without processing the organic layer 112W by a photolithography method or the like.

The above is the description of the structure examples of the display device.

### [Pixel Layout]

Pixel layouts different from the layout in FIG. 15A are mainly described below. Arrangement of subpixels including light-emitting devices and light-receiving device is not particularly limited and a variety of layouts can be used.

Examples of a planar shape of the subpixel include polygons such as a triangle, a tetragon (including a rectangle and a square), and a pentagon; polygons with rounded corners; an ellipse; and a circle. Here, a planar shape of the subpixel corresponds to a planar shape of a light-emitting region of a light-emitting device and a planar shape of a light-receiving region of a light-receiving device.

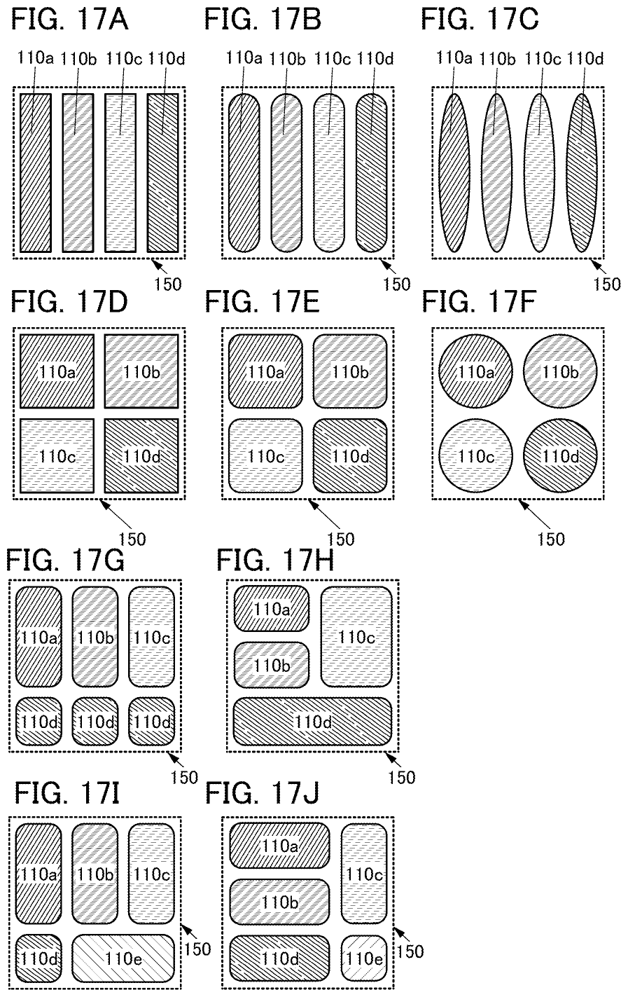

As illustrated in FIGS. 17A to 17H, a pixel 150 can include four types of subpixels (a subpixel 110a, a subpixel 110b, a subpixel 110c, and a subpixel 110d).

The pixels 150 illustrated in FIGS. 17A to 17C employ stripe arrangement.

FIG. 17A illustrates an example where each subpixel has a rectangular planar shape, FIG. 17B illustrates an example where each subpixel has a planar shape formed by combining two half circles and a rectangle, and FIG. 17C illustrates an example where each subpixel has an elliptical planar shape.

The pixels 150 illustrated in FIGS. 17D to 17F employ matrix arrangement.

FIG. 17D illustrates an example where each subpixel has a square planar shape, FIG. 17E illustrates an example where each subpixel has a rough square planar shape with rounded corners, and FIG. 17F illustrates an example where each subpixel has a circular planar shape.

FIG. 17G illustrates an example where one pixel 150 is composed of subpixels arranged in two rows and three columns.

The pixel 150 illustrated in FIG. 17G includes three subpixels (the subpixels 110a, 110b, and 110c) in the upper row (first row) and three subpixels 110d in the lower row (second row). In other words, the pixel 150 includes the subpixel 110a and the subpixel 110d in the left column (first column), the subpixel 110b and another subpixel 110d in the center column (second column), and the subpixel 110c and another subpixel 110d in the right column (third column). Matching the positions of the subpixels in the upper row and the lower row as illustrated in FIG. 17G enables dust and the like that would be produced in the manufacturing process of the display device to be removed efficiently. Thus, a display device having high display quality can be provided.

FIG. 17H illustrates an example where one pixel 150 is composed of subpixels arranged in three rows and two columns.

The pixel 150 illustrated in FIG. 17H includes the subpixel 110a in the upper row (first row), the subpixel 110b in the center row (second row), the subpixel 110c across the first and second rows, and one subpixel (the subpixel 110d) in the lower row (third row). In other words, the pixel 150 includes the subpixels 110a and 110b in the left column (first column), the subpixel 110c in the right column (second column), and the subpixel 110d across these two columns.

The pixel 150 illustrated in any of FIGS. 17A to 17H includes four subpixels of the subpixels 110a, 110b, 110c, and 110d. In the display device of one embodiment of the present invention, three of the four subpixels of the pixel 150 can each include a light-emitting device and the remaining one subpixel can include a light-receiving device.

For example, it is preferable that the subpixel 110a include the light-emitting device 110R emitting red light, the subpixel 110b include the light-emitting device 110G emitting green light, the subpixel 110c include the light-emitting device 110B emitting blue light, and the subpixel 110d include the light-receiving device 110S. When the pixel 150 illustrated in FIG. 17G has such a structure, the light-emitting devices 110R, 110G, and 110B are arranged in stripe arrangement, improving the display quality. When the pixel 150 illustrated in FIG. 17H has such a structure, the light-emitting devices 110R, 110G, and 110B are arranged in what is called an S-stripe pattern, improving the display quality. Note that three of the four subpixels may each include the light-emitting device 110W emitting white light, except for the subpixel including the light-receiving device.

There is no particular limitation on the wavelength of light detected by the subpixel including the light-receiving device 110S. The subpixel can have a structure in which one or both of infrared light and visible light can be detected.

As illustrated in FIGS. 17I and 17J, the pixel 150 can include five types of subpixels (the subpixel 110a, the subpixel 110b, the subpixel 110c, the subpixel 110d, and the subpixel 110e).

FIG. 17I illustrates an example where one pixel 150 is composed of subpixels arranged in two rows and three columns.

The pixel 150 illustrated in FIG. 17I includes three subpixels (the subpixels 110a, 110b, and 110c) in the upper row (first row) and two subpixels (the subpixels 110d and 110e) in the lower row (second row). In other words, the pixel 150 includes the subpixel 110a and the subpixel 110d in the left column (first column), the subpixel 110b in the center column (second column), the subpixel 110c in the right column (third column), and the subpixel 110e across the second and third columns.

FIG. 17J illustrates an example where one pixel 150 is composed of subpixels arranged in three rows and two columns.

The pixel 150 illustrated in FIG. 17J includes the subpixel 110a in the upper row (first row), the subpixel 110b in the center row (second row), the subpixel 110c across the first and second rows, and two subpixels (the subpixels 110d and 110e) in the lower row (third row). In other words, the pixel 150 includes the subpixels 110a, 110b, and 110d in the left column (first column), and the subpixels 110c and 110e in the right column (second column).

For example, it is preferable that in the pixel 150 illustrated in each of FIGS. 17I and 17J, the subpixel 110a include the light-emitting device 110R emitting red light, the subpixel 110b include the light-emitting device 110G emitting green light, and the subpixel 110c include the light-emitting device 110B emitting blue light. When the pixel 150 illustrated in FIG. 17I has such a structure, the light-emitting devices 110R, 110G, and 110B are arranged in stripe arrangement, improving the display quality. When the pixel 150 illustrated in FIG. 17J has such a structure, the light-emitting devices 110R, 110G, and 110B are arranged in what is called an S-stripe pattern, improving the display quality. Note that all of the three subpixels may each include the light-emitting device 110W emitting white light.

In the pixel 150 illustrated in each of FIGS. 17I and 17J, for example, it is preferable to use the light-receiving device 110S in at least one of the subpixels 110d and 110e. In the case where light-receiving devices are used in both the subpixels 110d and 110e, the light-receiving devices may have different structures. For example, the wavelength ranges of detected light may be different at least partly. Specifically, one of the subpixels 110d and 110e may include a light-receiving device mainly detecting visible light and the other may include a light-receiving device mainly detecting infrared light.

In the pixel 150 illustrated in each of FIGS. 17I and 17J, for example, it is preferable that one of the subpixels 110d and 110e include the light-receiving device 110S and the other include a light-emitting device that can be used as a light source. For example, it is preferable that one of the subpixels 110d and 110e include a light-emitting device emitting infrared light and the other include a light-receiving device detecting infrared light.

For example, with the pixel 150 including five subpixels of the light-emitting devices 110R, 110G, and 110B, a light-emitting device emitting infrared light, and the light-receiving device 110S, while an image is displayed using the light-emitting devices 110R, 110G, and 110B, the light-emitting device emitting infrared light can be used as a light source and the light-receiving device 110S can detect reflected light of the infrared light emitted from the light-emitting device emitting infrared light.

As described above, the pixel composed of the subpixels each including the light-emitting device or the light-receiving device can employ any of a variety of layouts in the display device of one embodiment of the present invention.

Note that in a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a planar shape of a light-emitting device may be a polygonal shape with rounded corners, an elliptical shape, a circular shape, or the like.

Furthermore, in the manufacturing method of the display panel of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film might have a shape different from a desired shape by processing. As a result, a planar shape of the EL layer might be a polygonal shape with rounded corners, an elliptical shape, a circular shape, or the like. For example, when a resist mask with a square planar shape is intended to be formed, a resist mask with a circular planar shape might be formed, and the planar shape of the EL layer might be circular.

To obtain a desired planar shape of the EL layer, a technique of correcting a mask pattern in advance so that a transferred pattern agrees with a design pattern (an optical proximity correction (OPC) technique) may be used. Specifically, with the OPC technique, a pattern for correction is added to a corner portion or the like of a figure on a mask pattern.

The above is the description of the pixel layouts.

At least part of this embodiment can be implemented in combination with any of the other embodiments described in this specification, as appropriate.

### Embodiment 3

In this embodiment, other structure examples of a display device (display panel) that can be used for the electronic device of one embodiment of the present invention are described. Display devices described below as examples can be used as the display device 100 or the like in Embodiment 1.

The display device in this embodiment can be a high-resolution display device. For example, the display device of one embodiment of the present invention can be used for display portions of information terminals (wearable devices) such as watch-type or bracelet-type information terminals and display portions of wearable devices capable of being worn on a head, such as a VR device (e.g., an HMD) and a glasses-type AR device.

### [Display Module]

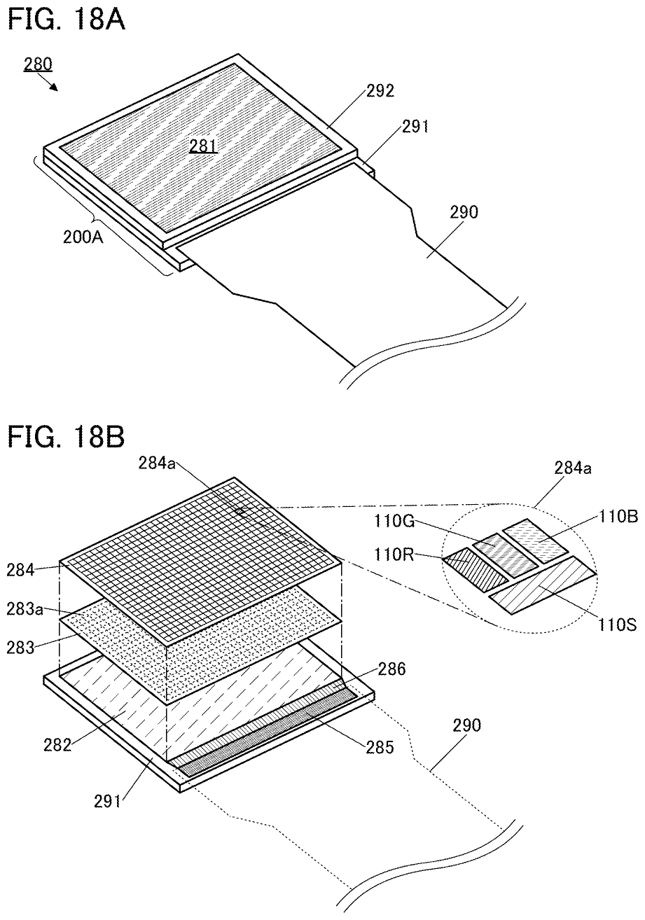

FIG. 18A is a perspective view of a display module 280. The display module 280 includes a display device 200A and an FPC 290. Note that the display panel included in the display module 280 is not limited to the display device 200A and may be any of display devices 200B to 200G to be described later.

The display module 280 includes a substrate 291 and a substrate 292. The display module 280 includes a display portion 281. The display portion 281 is a region where an image is displayed.

FIG. 18B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 18B. The pixel 284a includes the light-emitting device 110R emitting red light, the light-emitting device 110G emitting green light, the light-emitting device 110B emitting blue light, and the light-receiving device 110S receiving external light.

The pixel circuit portion 283 includes a plurality of pixel circuits 283a arranged periodically. One pixel circuit 283a controls light emission from three light-emitting devices included in one pixel 284a and photoelectric conversion of one light-receiving device. One pixel circuit 283a may include three circuits each of which controls light emission from one light-emitting device and one circuit that controls photoelectric conversion of one light-receiving device. For example, the pixel circuit 283a can include at least one selection transistor, one current control transistor (driving transistor), and a capacitor for each of a light-emitting device and a light-receiving device. In this case, a gate signal is input to a gate of the selection transistor, and a source signal is input to a source of the selection transistor. Thus, an active matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high level of immersion can be performed. Without being limited thereto, the display module 280 can be suitably used for electronic devices including a relatively small display portion. For example, the display module 280 can be favorably used in a display portion of a wearable electronic device, such as a wrist watch.

### [Display Device 200A]

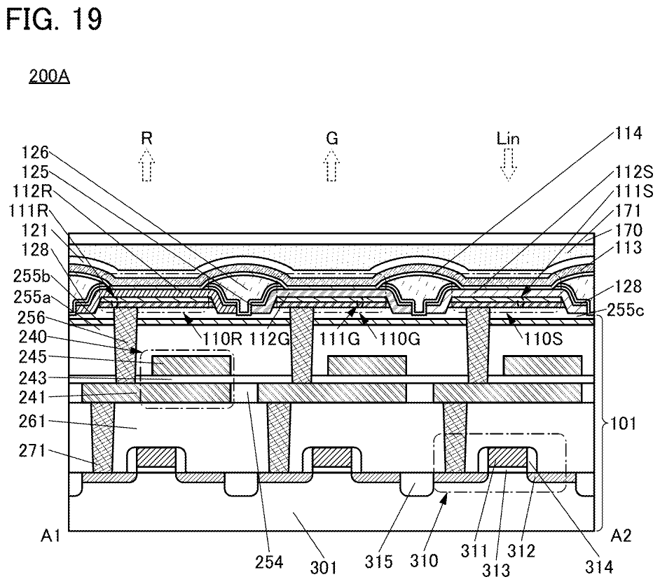

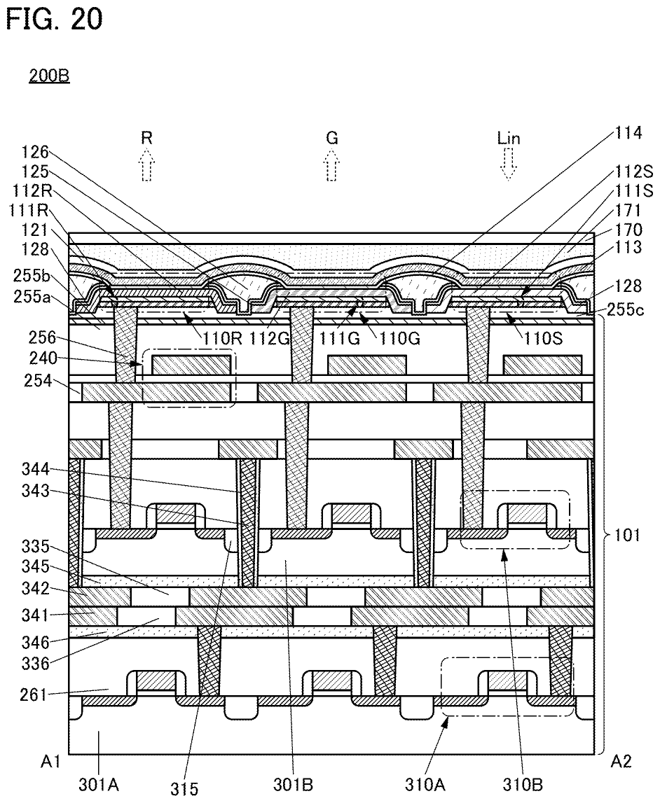

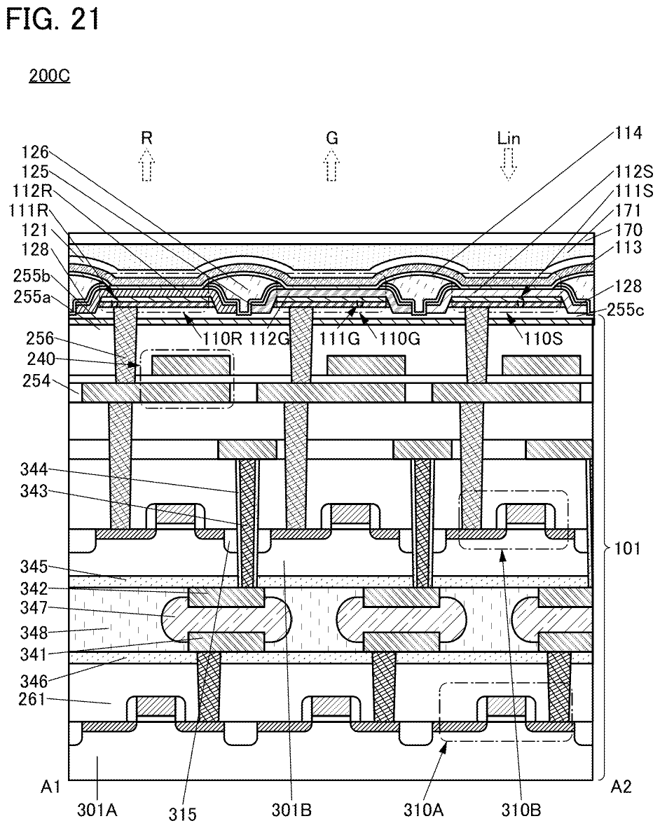

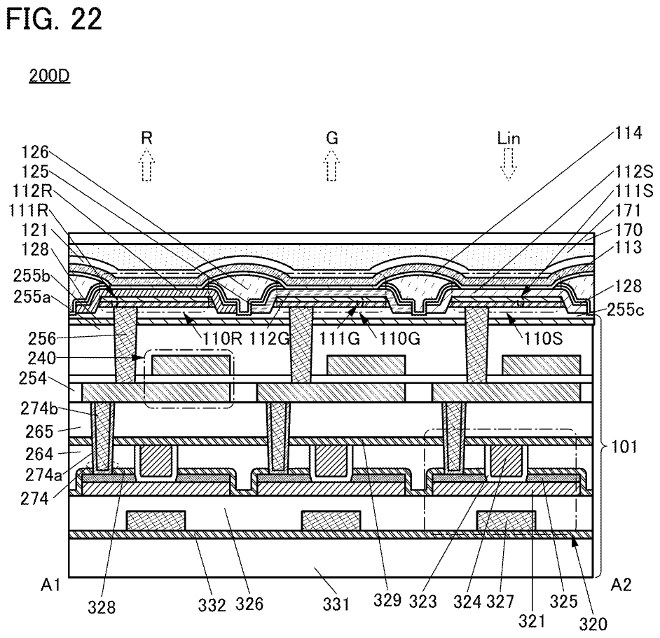

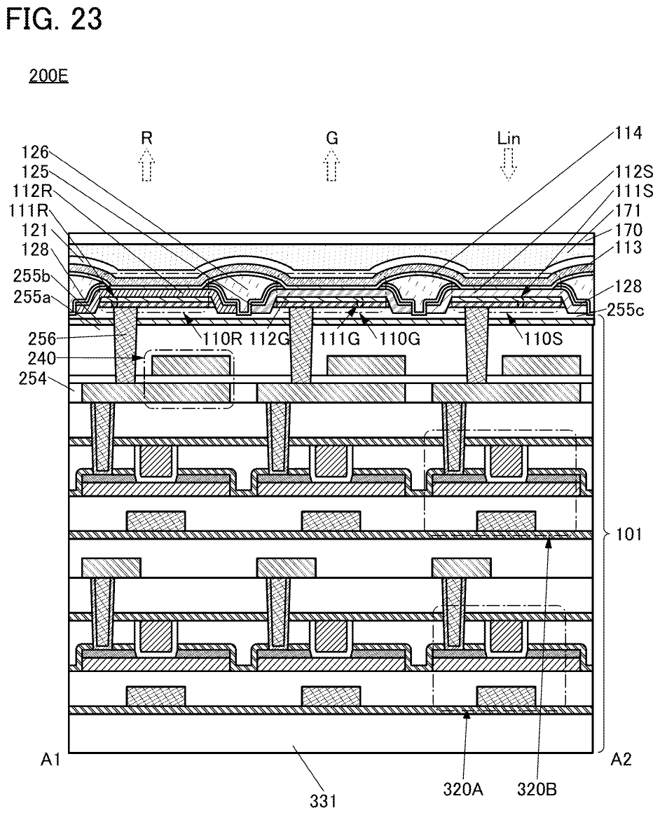

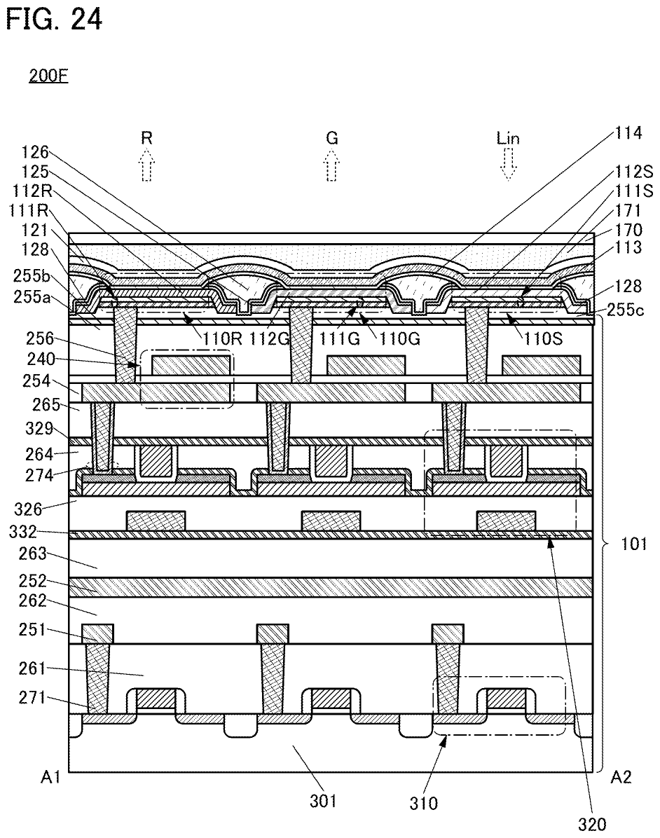

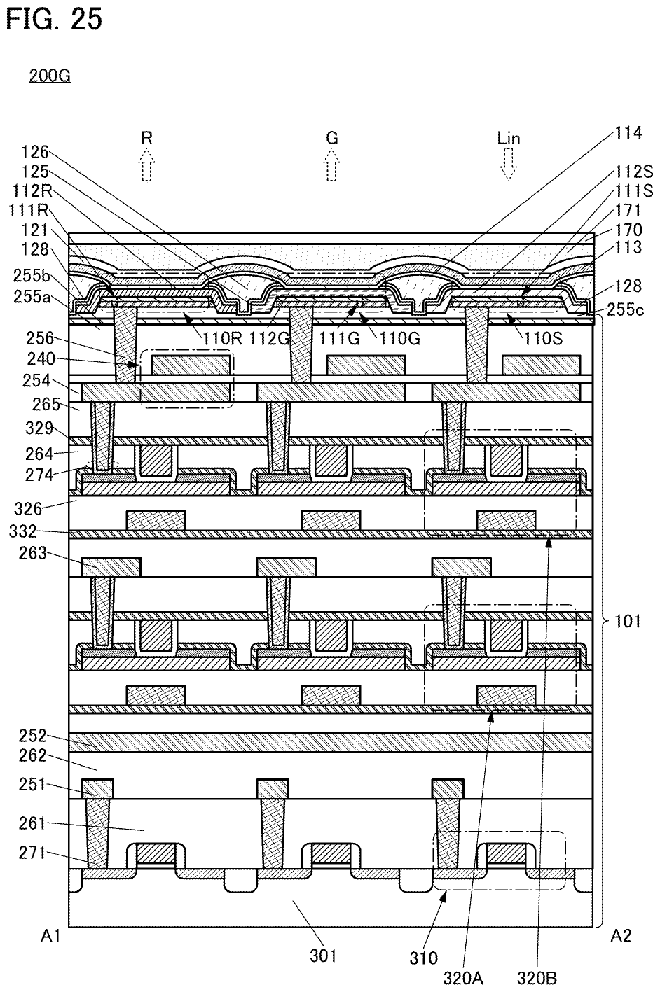

The display device 200A illustrated in FIG. 19 includes a substrate 301, the light-emitting devices 110R and 110G, the light-receiving device 110S, a capacitor 240, and a transistor 310. Note that FIG. 19 and FIG. 20, FIG. 21, FIG. 22, FIG. 23, FIG. 24, and FIG. 25 to be described later are schematic cross-sectional views taken along dashed-dotted line A1-A2 in FIG. 15A.

The substrate 301 corresponds to the substrate 291 illustrated in FIGS. 18A and 18B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layers 255a, 255b, and 255c. For example, it is preferred that a silicon oxide film be used as the insulating layers 255a and 255c and a silicon nitride film be used as the insulating layer 255b. This enables the insulating layer 255b to function as an etching protective film. Although this embodiment describes an example in which part of the insulating layer 255c is etched to form a recessed portion, the recessed portion is not necessarily provided in the insulating layer 255c.

The light-emitting device 110R, the light-emitting device 110G, the light-emitting device 110B (not illustrated), and the light-receiving device 110S are provided over the insulating layer 255c. The description in the above embodiment can be referred to for the structures of the light-emitting devices 110R, 110G, and 110B and the light-receiving device 110S.

In the display device 200A, since the light-emitting devices of different colors are separately formed, the difference between the chromaticity at low luminance emission and that at high luminance emission is small. Furthermore, since the organic layers 112R, 112G, and 112B (not illustrated) are separated from each other, crosstalk generated between adjacent subpixels can be prevented while the display device 200A has high resolution. Accordingly, the display panel can have high resolution and high display quality.

In regions between adjacent light-emitting devices and between a light-emitting device and a light-receiving device that are adjacent to each other, the insulating layer 125, the resin layer 126, and the layer 128 are provided.

The pixel electrodes 111R, 111G, 111B (not illustrated), and 111S are each electrically connected to one of the source and the drain of the transistor 310 through a plug 256 embedded in the insulating layers 255a, 255b, 255c, and 243, the conductive layer 241 embedded in the insulating layer 254, and the plug 271 embedded in the insulating layer 261. The top surface of the insulating layer 255c and the top surface of the plug 256 are level with or substantially level with each other. Any of a variety of conductive materials can be used for the plugs.

The protective layer 121 is provided over the light-emitting devices 110R, 110G, and 110B, and the light-receiving device 110S. A substrate 170 is bonded above the protective layer 121 with an adhesive layer 171.

An insulating layer covering an end portion of the top surface of the pixel electrode 111 is not provided between two adjacent pixel electrodes 111. Thus, the distances between adjacent light-emitting devices and between a light-emitting device and a light-receiving device that are adjacent to each other can be extremely shortened. Accordingly, the display device can have high resolution or high definition.

### [Display Device 200B]

The display device 200B illustrated in FIG. 20 has a structure in which a transistor 310A and a transistor 310B each having a channel formed in a semiconductor substrate are stacked. Note that in the following description of display panels, the description of portions similar to those of the above-described display panel may be omitted.

In the display device 200B, a substrate 301B provided with the transistor 310B, the capacitor 240, the light-emitting devices, and the light-receiving device is attached to a substrate 301A provided with the transistor 310A.

Here, an insulating layer 345 is provided on a bottom surface (a surface on the substrate 301A side) of the substrate 301B. An insulating layer 346 is provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 121 can be used.

The substrate 301B is provided with a plug 343 that penetrates the substrate 301B and the insulating layer 345. An insulating layer 344 functioning as a protective layer is preferably provided to cover a side surface of the plug 343.

A conductive layer 342 is provided on the bottom side (the substrate 301A side) of the substrate 301B with the insulating layer 345 therebetween. The conductive layer 342 is embedded in an insulating layer 335. Bottom surfaces (surfaces on the substrate 301A side) of the conductive layer 342 and the insulating layer 335 are planarized. The conductive layer 342 is electrically connected to the plug 343.

A conductive layer 341 is provided over the insulating layer 346 over the substrate 301A. The conductive layer 341 is embedded in an insulating layer 336. Top surfaces of the conductive layer 341 and the insulating layer 336 are planarized.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### [Display Device 200C]

The display device 200C illustrated in FIG. 21 has a structure in which the conductive layer 341 and the conductive layer 342 are bonded to each other with a bump 347.

As illustrated in FIG. 21, providing the bump 347 between the conductive layer 341 and the conductive layer 342 enables the conductive layers 341 and 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 which are illustrated in FIG. 20 may be omitted.

### [Display Device 200D]

The display device 200D illustrated in FIG. 22 differs from the display device 200A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIGS. 18A and 18B.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the substrate 331 side. As the insulating layer 332, it is preferable to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used as the semiconductor layer 321. The pair of conductive layers 325 is provided on and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the top surface of the semiconductor layer 321 and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and insulating layers 329 and 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 and the like into the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

There is no particular limitation on the structure of the transistors included in the display device of this embodiment. For example, a planar transistor, a staggered transistor, or an inverted staggered transistor can be used. A top-gate transistor or a bottom-gate transistor can be used. Gate electrodes may be provided above and below a semiconductor layer where a channel is formed.

The structure in which the semiconductor layer where a channel is formed is provided between two gate electrodes is used for the transistor 320. The two gate electrodes may be connected to each other and supplied with the same signal to operate the transistor. Alternatively, the threshold voltage of the transistor may be controlled by applying a potential for controlling the threshold voltage to one of the two gate electrodes and a potential for driving to the other of the two gate electrodes.

There is no particular limitation on the crystallinity of a semiconductor material used in the semiconductor layer of the transistor, and an amorphous semiconductor, a single crystal semiconductor, or a semiconductor having crystallinity other than single crystal (a microcrystalline semiconductor, a polycrystalline semiconductor, or a semiconductor partly including crystal regions) can be used. It is preferable to use a single crystal semiconductor or a semiconductor having crystallinity, in which case deterioration of the transistor characteristics can be suppressed.

The band gap of a metal oxide included in the semiconductor layer of the transistor is preferably 2 eV or more, further preferably 2.5 eV or more. The use of such a metal oxide having a wide band gap can reduce the off-state current of the OS transistor.

A metal oxide preferably contains at least indium or zinc, and further preferably contains indium and zinc. A metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, a semiconductor layer of a transistor may contain silicon. Examples of silicon include amorphous silicon and crystalline silicon (e.g., low-temperature polysilicon or single crystal silicon).

Examples of the metal oxide that can be used for the semiconductor layer include indium oxide, gallium oxide, and zinc oxide. The metal oxide preferably contain two or three kinds selected from indium, the element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more of aluminum, gallium, yttrium, and tin.

It is particularly preferable that an oxide containing indium, gallium, and zinc (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium, aluminum, and zinc (also referred to as IAZO). Alternatively, it is preferable to use an oxide containing indium, aluminum, gallium, and zinc (also referred to as IAGZO).

When the metal oxide used for the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked structure of a first metal oxide layer having In:M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be favorably employed. In particular, gallium or aluminum is preferably used as the element M.

Alternatively, a stacked structure of one selected from indium oxide, indium gallium oxide, and IGZO, and one selected from IAZO, IAGZO, and ITZO (registered trademark) may be employed, for example.

As the oxide semiconductor having crystallinity, a c-axis aligned crystalline oxide semiconductor (CAAC-OS), a nanocrystalline oxide semiconductor (nc-OS), and the like are given.

The OS transistor has much higher field-effect mobility than a transistor containing amorphous silicon. In addition, the OS transistor has an extremely low leakage current between a source and a drain in an off state (the leakage current is also referred to as an off-state current), and charge accumulated in a capacitor that is connected in series to the transistor can be held for a long period. Furthermore, the power consumption of the display device can be reduced with the OS transistor.

To increase the emission luminance of the light-emitting device included in a pixel circuit, it is necessary to increase the amount of current flowing through the light-emitting device. For this, it is necessary to increase the source-drain voltage of a driving transistor included in the pixel circuit. Since the OS transistor has a higher withstand voltage between the source and the drain than a Si transistor, a high voltage can be applied between the source and the drain of the OS transistor. Thus, with the use of an OS transistor as a driving transistor included in the pixel circuit, the amount of current flowing through the light-emitting device can be increased, resulting in an increase in emission luminance of the light-emitting device.

Assuming that the transistor operates in a saturation region, a change in the amount of current between the source and the drain, with respect to a fluctuation in the gate-source voltage, in the OS transistor is smaller than that in the Si transistor. Thus, with the use of an OS transistor as a driving transistor included in the pixel circuit, the amount of current flowing between the source and the drain can be accurately specified based on a fluctuation of the gate-source voltage, which enables the amount of current flowing through the light-emitting device to be controlled. Accordingly, the gray level in the pixel circuit can be increased.

As saturation characteristics of current flowing when the transistor operates in a saturation region, the OS transistor can make current (saturation current) flow more stably than the Si transistor even when the source-drain voltage gradually increases. Thus, with the use of an OS transistor as a driving transistor, current can be made to flow stably through the light-emitting device, for example, even when a variation in current-voltage characteristics of the EL device occurs. In other words, the amount of current between the source and the drain is less changed in the OS transistor operating in the saturation region even when the source-drain voltage is made higher. As a result, the emission luminance of the light-emitting device can be stabilized.

As described above, with the use of an OS transistor as a driving transistor included in the pixel circuit, it is possible to achieve “inhibition of black floating”, “increase in emission luminance”, “increase in gray level”, “inhibition of variation in light-emitting devices”, and the like.

### [Display Device 200E]

The display device 200E illustrated in FIG. 23 has a structure in which a transistor 320A and a transistor 320B each including an oxide semiconductor in a semiconductor where a channel is formed are stacked.

The description of the display device 200D can be referred to for the transistor 320A, the transistor 320B, and other peripheral structures.

Although the structure in which two transistors including an oxide semiconductor are stacked is described, the present invention is not limited thereto. For example, three or more transistors may be stacked.

### [Display Device 200F]

The display device 200F illustrated in FIG. 24 has a structure in which the transistor 310 having a channel formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display panel can be downsized as compared with the case where a driver circuit is provided around a display region.

### [Display Device 200G]

The display device 200G illustrated in FIG. 25 has a structure in which the transistor 310 having a channel formed in the substrate 301 and the transistors 320A and 320B each including a metal oxide in a semiconductor layer where a channel is formed are stacked.

The transistor 320A can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 320B may be used as a transistor included in the pixel circuit or a transistor included in the driver circuit. The transistor 310, the transistor 320A, and the transistor 320B can also be used as transistors included in a variety of circuits such as an arithmetic circuit and a memory circuit.

At least part of this embodiment can be implemented in combination with any of the other embodiments described in this specification, as appropriate.

### Embodiment 4

In this embodiment, a light-emitting device and a light-receiving device that can be used in the display device of one embodiment of the present invention are described.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

In this specification and the like, a structure in which at least light-emitting layers of light-emitting devices with different emission wavelengths are separately formed may be referred to as a side-by-side (SBS) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be clearly distinguished from each other depending on the cross-sectional shape, properties, or the like. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

As the light-emitting device, an OLED or a QLED is preferably used, for example. Examples of a light-emitting substance contained in the light-emitting device include a substance exhibiting fluorescence (fluorescent material), a substance exhibiting phosphorescence (phosphorescent material), a substance exhibiting thermally activated delayed fluorescence (TADF material), and an inorganic compound (e.g., a quantum dot material). A light-emitting diode (LED) such as a micro-LED can also be used as the light-emitting device.

The light-emitting device can emit infrared, red, green, blue, cyan, magenta, yellow, or white light, for example. When the light-emitting device has a microcavity structure, the color purity can be increased.

### [Light-Emitting Device]

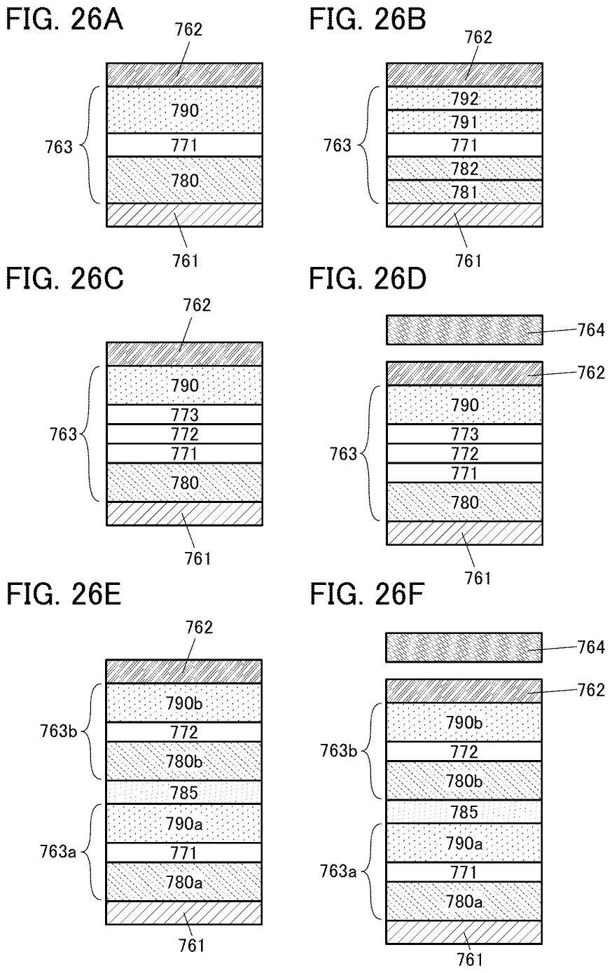

As illustrated in FIG. 26A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 26A is referred to as a single structure in this specification.

FIG. 26B is a modification example of the EL layer 763 included in the light-emitting device illustrated in FIG. 26A. Specifically, the light-emitting device illustrated in FIG. 26B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771, 772, and 773) are provided between the layers 780 and 790 as illustrated in FIGS. 26C and 26D are other variations of the single structure. Although FIGS. 26C and 26D each illustrate an example in which three light-emitting layers are included, the number of light-emitting layers in a light-emitting device having a single structure may be two or four or more. A light-emitting device having a single structure may include a buffer layer between two light-emitting layers. A carrier transport layer (a hole-transport layer or an electron-transport layer) can be used as the buffer layer, for example.

A structure in which a plurality of light-emitting units (light-emitting units 763a and 763b) are connected in series with a charge-generation layer (also referred to as an intermediate layer) 785 therebetween as illustrated in FIGS. 26E and 26F is referred to as a tandem structure in this specification. The tandem structure may be referred to as a stack structure. The tandem structure enables a light-emitting device capable of high-luminance light emission. Furthermore, the tandem structure allows the amount of current needed for obtaining the same luminance to be reduced as compared to the case of using a single structure, and thus can improve the reliability.

Note that FIGS. 26D and 26F each illustrate an example in which the display device includes a layer 764 overlapping with the light-emitting device. FIG. 26D is an example in which the layer 764 overlaps with the light-emitting device illustrated in FIG. 26C and FIG. 26F illustrates an example in which the layer 764 overlaps with the light-emitting device illustrated in FIG. 26E. In FIGS. 26D and 26F, a conductive film that transmits visible light is used for the upper electrode 762 so that light is extracted from the upper electrode 762 side.

One or both of a color conversion layer and a color filter (coloring layer) can be used as the layer 764.

In FIGS. 26C and 26D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that emits blue light, blue light from the light-emitting device can be extracted as it is. In each of a subpixel that emits red light and a subpixel that emits green light, a color conversion layer is provided as the layer 764 illustrated in FIG. 26D for converting blue light from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIGS. 26C and 26D, light-emitting substances that emit light of different colors may be used for the light-emitting layers 771, 772, and 773. When the light-emitting layers 771, 772, and 773 emit light of complementary colors, the light emitted from the light-emitting layer 771, the light emitted from the light-emitting layer 772, and the light emitted from the light-emitting layer 773 are mixed and thus white light emission can be obtained as a whole. The light-emitting device having a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 26D. When white light passes through a color filter, light of a desired color can be obtained.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer containing a light-emitting substance emitting blue (B) light and a light-emitting layer containing a light-emitting substance emitting yellow (Y) light are preferably included. Such a structure may be referred to as a BY single structure.

In the light-emitting device that emits white light, two or more kinds of light-emitting substances are preferably contained. To obtain white light emission, the two or more kinds of light-emitting substances are selected so as to emit light of complementary colors. For example, when emission colors of a first light-emitting layer and a second light-emitting layer are complementary colors, the light-emitting device can emit white light as a whole. The same applies to a light-emitting device including three or more light-emitting layers.

In FIGS. 26C and 26D, the layers 780 and 790 may each have a stacked-layer structure of two or more layers as illustrated in FIG. 26B.

In FIGS. 26E and 26F, light-emitting substances that emit light of the same color, or moreover, the same light-emitting substance may be used for the light-emitting layers 771 and 772. For example, in light-emitting devices included in subpixels emitting light of different colors, a light-emitting substance that emits blue light can be used for each of the light-emitting layer 771 and the light-emitting layer 772. In the subpixel that emits blue light, blue light from the light-emitting device can be extracted as it is. In each of the subpixel that emits red light and the subpixel that emits green light, a color conversion layer is provided as the layer 764 illustrated in FIG. 26F for converting blue light from the light-emitting device into light with a longer wavelength, so that red light or green light can be extracted. As the layer 764, both a color conversion layer and a coloring layer are preferably used.

In the case where light-emitting devices with the structure illustrated in FIG. 26E or FIG. 26F are used in subpixels emitting light of different colors, light-emitting substances may be different between the subpixels. Specifically, in the light-emitting device included in the subpixel emitting red light, a light-emitting substance that emits red light can be used for each of the light-emitting layer 771 and the light-emitting layer 772. In the light-emitting device included in the subpixel emitting green light, a light-emitting substance that emits green light can be used for each of the light-emitting layer 771 and the light-emitting layer 772. In the light-emitting device included in the subpixel emitting blue light, a light-emitting substance that emits blue light can be used for each of the light-emitting layer 771 and the light-emitting layer 772. A display device with such a structure includes a light-emitting device with a tandem structure and can be regarded to have an SBS structure. Thus, the display device can have advantages of both of a tandem structure and an SBS structure. Accordingly, a highly reliable light-emitting device capable of high-luminance light emission can be obtained.

In FIGS. 26E and 26F, light-emitting substances that emit light of different colors may be used for the light-emitting layers 771 and 772. When the light-emitting layers 771 and 772 emit light of complementary colors, the light emitted from the light-emitting layer 771 and the light emitted from the light-emitting layer 772 are mixed and thus white light emission can be obtained as a whole. A color filter may be provided as the layer 764 illustrated in FIG. 26F. When white light passes through a color filter, light of a desired color can be obtained.

Although FIGS. 26E and 26F each illustrate an example in which the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIGS. 26E and 26F each illustrate an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 26E and 26F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

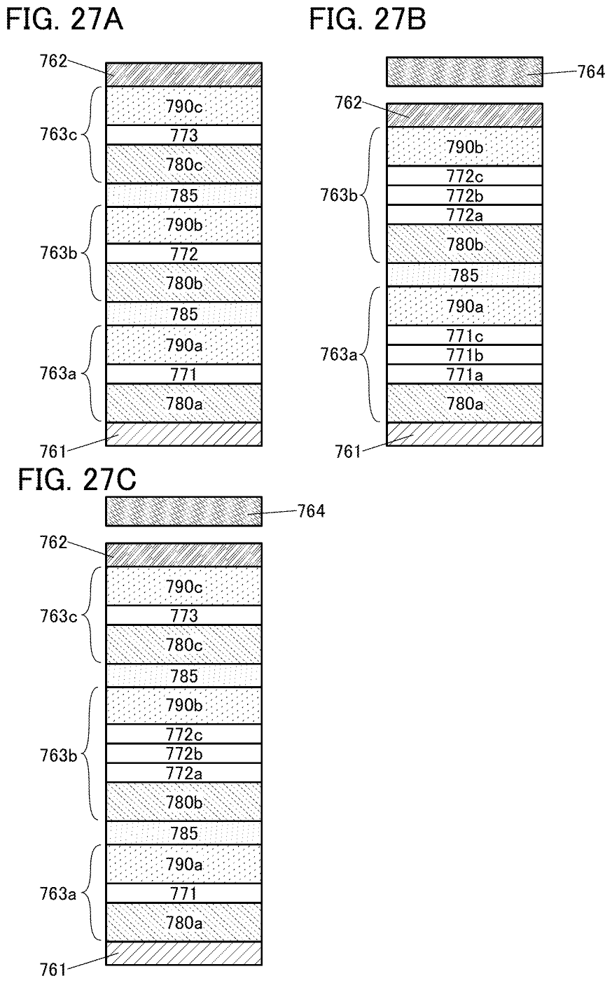

Examples of the light-emitting device with a tandem structure are structures illustrated in FIGS. 27A to 27C.

FIG. 27A shows a structure including three light-emitting units. In the structure illustrated in FIG. 27A, a plurality of light-emitting units (light-emitting units 763a, 763b, and 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 27A, the light-emitting layers 771, 772, and 773 preferably contain light-emitting substances that emit light of the same color. Specifically, the light-emitting layers 771, 772, and 773 can each contain a light-emitting substance that emits red (R) light (i.e., an R\R\R three-unit tandem structure), can each contain a light-emitting substance that emits green (G) light (i.e., a G\G\G three-unit tandem structure), or can each contain a light-emitting substance that emits blue (B) light (i.e., a B\B\B three-unit tandem structure). Note that “a\b” means that a light-emitting unit containing a light-emitting substance that emits light of the color “b” is provided over a light-emitting unit containing a light-emitting substance that emits light of the color “a” with a charge-generation layer therebetween.

In FIG. 27A, light-emitting substances that emit light of different colors may be used for some or all of the light-emitting layers 771, 772, and 773. Examples of a combination of emission colors for the light-emitting layers 771, 772, and 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each containing a plurality of light-emitting substances are stacked as illustrated in FIG. 27B. FIG. 27B illustrates a structure in which a plurality of light-emitting units (light-emitting units 763a and 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 27B, light-emitting substances emitting light of complementary colors are selected for the light-emitting layers 771a, 771b, and 771c to obtain white (W) light emission as a whole. Furthermore, light-emitting substances for the light-emitting layers 772a, 772b, and 772c are selected so as to emit light of complementary colors to obtain white (W) light emission as a whole. That is, the structure illustrated in FIG. 27B is a two-unit tandem structure of W\W. Note that there is no particular limitation on the stacking order of light-emitting substances that emit light of complementary colors, and a practitioner can select an optimum stacking order as appropriate. Although not illustrated, a three-unit tandem structure of W\W\W or a tandem structure with four or more units may be employed.

In the case of a light-emitting device with a tandem structure, any of the following structure may be employed, for example: a two-unit tandem structure of B including a light-emitting unit that emits yellow (Y) light and a light-emitting unit that emits blue (B) light; a two-unit tandem structure of R·G\B including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of the color “a” and a light-emitting substance that emits light of the color “b”.

Alternatively, a light-emitting unit containing one light-emitting substance and a light-emitting unit containing a plurality of light-emitting substances may be used in combination as illustrated in FIG. 27C.

Specifically, in the structure illustrated in FIG. 27C, a plurality of light-emitting units (the light-emitting units 763a, 763b, and 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 27C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display device includes a light-emitting device emitting infrared light, a conductive film transmitting visible light and infrared light is used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably provided between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (hole-transport material) and a substance having a high electron-transport property (electron-transport material) can be used. As the hole-transport material, a later-described material having a high hole-transport property that can be used for the hole-transport layer can be used. As the electron-transport material, a later-described material having a high electron-transport property that can be used for the electron-transport layer can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and contains a material having a high hole-injection property. Examples of a material having a high hole-injection property include an aromatic amine compound and a composite material containing a hole-transport material and an acceptor material (electron-accepting material).

As the hole-transport material, an aftermentioned material having a high hole-transport property usable for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material having a high hole-injection property, a material containing a hole-transport material and the above-described oxide of a metal belonging to Group 4 to Group 8 of the periodic table (typified by molybdenum oxide) may be used, for example.

The hole-transport layer transports holes injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and containing a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and contains a material having a high electron-injection property. As the material having a high electron-injection property, an alkali metal, an alkaline earth metal, or a compound thereof can be used. As the material having a high electron-injection property, a composite material containing an electron-transport material and a donor material (electron-donating material) can also be used.

The LUMO level of the material having a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiO_{X}), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material. For example, the charge-generation region preferably contains the above-described hole-transport material and acceptor material that can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) and transferring electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the charge-generation region, the electron-injection buffer layer, and the electron-relay layer cannot be clearly distinguished from one another depending on the cross-sectional shape or properties in some cases.

The charge-generation layer may contain a donor material instead of an acceptor material. For example, the charge-generation layer may include a layer containing the above-described electron-transport material and donor material that can be used for the electron-injection layer.

When the charge-generation layer is provided between two light-emitting units to be stacked, an increase in driving voltage can be inhibited.

### [Light-Receiving Device]

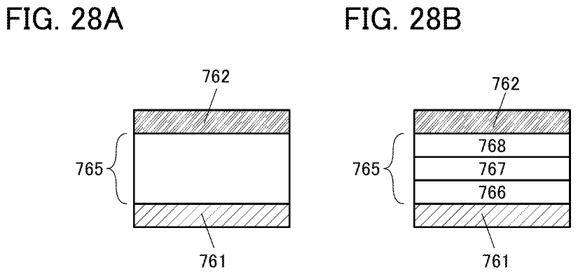

As illustrated in FIG. 28A, the light-receiving device includes a layer 765 between a pair of electrodes (the lower electrode 761 and the upper electrode 762). The layer 765 includes at least one active layer, and may further include another layer.

FIG. 28B is a variation example of the layer 765 included in the light-receiving device illustrated in FIG. 28A. Specifically, the light-receiving device illustrated in FIG. 28B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layers 766 and 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed by an evaporation method (including a vacuum evaporation method), a transfer method, a printing method, an inkjet method, a coating method, or the like.

The active layer included in the light-receiving device includes a semiconductor. Examples of the semiconductor include an inorganic semiconductor such as silicon and an organic semiconductor including an organic compound. This embodiment describes an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer are electron-accepting organic semiconductor materials such as fullerene (e.g., C₆₀ and C₇₀) and fullerene derivatives. Examples of fullerene derivatives include [6,6]-phenyl-C₇₁-butyric acid methyl ester (abbreviation: PC₇₀BM), [6,6]-phenyl-C₆₁-butyric acid methyl ester (abbreviation: PC₆₀BM), and 1′,1″,4′,4″-tetrahydro-di[1,4]methanonaphthaleno[1,2:2′,3′,56,60:2″,3″][5,6]fullerene-C₆₀ (abbreviation: ICBA).

Examples of the n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-yli dene)dimalononitrile (abbreviation: FT2TDMN).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Examples of the p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-th iophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may contain a mixture of three or more kinds of materials. For example, a third material may be mixed with an n-type semiconductor material and a p-type semiconductor material in order to extend the absorption wavelength range. In this case, the third material may be a low molecular compound or a high molecular compound.

In addition to the active layer, the light-receiving device may further include a layer containing any of a substance having a high hole-transport property, a substance having a high electron-transport property, a substance having a bipolar property (a substance having a high electron- and hole-transport property), and the like. Without limitation to the above, the light-receiving device may further include a layer containing any of a substance having a high hole-injection property, a hole-blocking material, a substance having a high electron-injection property, an electron-blocking material, and the like. Layers other than the active layer in the light-receiving device can be formed using a material that can be used for the light-emitting device.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

At least part of any of the structure examples, the drawings corresponding thereto, and the like described in this embodiment can be implemented in combination with any of the other structure examples, the other drawings, and the like as appropriate.

At least part of this embodiment can be implemented in combination with any of the other embodiments described in this specification, as appropriate.

This application is based on Japanese Patent Application Serial No. 2022-004227 filed with Japan Patent Office on Jan. 14, 2022, the entire contents of which are hereby incorporated by reference.

What is claimed is:

1. An electronic device comprising:
a housing comprising an optical device,
wherein the optical device comprises a display device and a lens,
wherein the display device comprises a light-emitting device and a light-receiving device,
wherein the lens is positioned on a display portion side of the display device, and
wherein the housing is configured to detect, with the use of the light-receiving device, a spot diameter of first light that is emitted from the light-emitting device and reflected by a detection target
wherein the housing is configured to move the lens and detect, with the use of the light-receiving device, a spot diameter of second light that is emitted from the light-emitting device and reflected by the detection target,
wherein the housing is configured to determine whether the spot diameter of the second light is smaller than the spot diameter of the first light,
wherein the housing is configured to further move the lens and detect, with the use of the light-receiving device, a spot diameter of third light that is emitted from the light-emitting device and reflected by the detection target in the case where the spot diameter of the second light is smaller than the spot diameter of the first light,
wherein the housing is configured to determine whether the spot diameter of the third light is smaller than the spot diameter of the second light, and
wherein the housing is configured to move the lens to a position at which the spot diameter of the first light has been detected, in the case where the spot diameter of the second light is larger than the spot diameter of the first light.

2. The electronic device according to claim 1, wherein the light-emitting device is configured to emit infrared light.

3. The electronic device according to claim 2, wherein the light-receiving device is configured to detect infrared light.

4. The electronic device according to claim 1, wherein the detection target is a user's eye.

5. The electronic device according to claim 1, wherein a diagonal of a display portion of the display device is shorter than a diameter of the lens.

6. The electronic device according to claim 1, wherein a pixel density of the display device is higher than or equal to 1000 ppi and lower than or equal to 20000 ppi.

7. The electronic device according to claim 1,
wherein the display device comprises a plurality of the light-emitting devices and a color filter, and
wherein the plurality of light-emitting devices each comprise an organic layer emitting white light.

8. The electronic device according to claim 7,
wherein the organic layer is divided between two adjacent light-emitting devices.

9. The light-emitting device according to claim 1,
wherein the display device comprises a first light-emitting device and a second light-emitting device, and
wherein the first light-emitting device and the second light-emitting device comprise different light-emitting materials.

10. The electronic device according to claim 1,
wherein the housing is connected to a mounting fixture, and
wherein the mounting fixture is configured to fix the housing to a user's head.

11. A method for operating an electronic device,
the electronic device comprising an optical device comprising a display device and a lens,
wherein the display device comprises a light-emitting device and a light-receiving device, and
wherein the lens is positioned on a display portion side of the display device,
the method comprising:
a first step of displaying an image;
a second step of detecting, with the use of the light-receiving device, a spot diameter of first light that is emitted from the light-emitting device and reflected by a detection target;
a third step of moving the lens and detecting, with the use of the light-receiving device, a spot diameter of second light that is emitted from the light-emitting device and reflected by the detection target;
a fourth step of determining whether the spot diameter of the second light is smaller than the spot diameter of the first light;
a fifth step of further moving the lens and detecting, with the use of the light-receiving device, a spot diameter of third light that is emitted from the light-emitting device and reflected by the detection target in the case where the spot diameter of the second light is smaller than the spot diameter of the first light;
a sixth step of determining whether the spot diameter of the third light is smaller than the spot diameter of the second light; and
a seventh step of moving the lens to a position at which the spot diameter of the first light has been detected, in the case where the spot diameter of the second light is larger than the spot diameter of the first light.

12. The method for operating an electronic device, according to claim 11, wherein, in the first step, the light-emitting device emits infrared light while the image is displayed.

13. The method for operating an electronic device, according to claim 12, wherein the light-receiving device detects a spot diameter of infrared light reflected by the detection target in the second step, the third step, and the fifth step.

14. The method for operating an electronic device, according to claim 11, wherein the detection target is a user's eye.

15. An electronic device comprising:
a housing comprising an optical device,
wherein the optical device comprises a display device and a lens,
wherein the lens is positioned on a display portion side of the display device,
wherein the housing is configured to detect a spot diameter of light that is emitted from the display device and reflected by a user's eye, and
wherein the housing is configured to move the lens to make the spot diameter smaller.

16. The electronic device according to claim 15,
wherein the housing is connected to a mounting fixture, and
wherein the mounting fixture is configured to fix the housing to a user's head.
